(19) United States
(12) Patent Application Publication
(10) Pub. No.: US 2024/0321936 A1
(43) Pub. Date: Sep. 26, 2024

(54) INTEGRATED DEVICE COMPRISING AN INDUCTOR AND A PATTERNED SHIELD STRUCTURE

(71) Applicant: QUALCOMM Incorporated, San Diego, CA (US)

(72) Inventors: Hsiao-Tsung YEN, San Diego, CA (US); Xingyi HUA, San Diego, CA (US); Jeongil Jay KIM, San Diego, CA (US)

(21) Appl. No.: 18/189,110

(22) Filed: Mar. 23, 2023

(51) Int. Cl. H01L 23/552; H01L 23/522

(52) U.S. Cl. CPC H01L 28/10; H01L 23/5227; H01L 23/552

(57) ABSTRACT

An integrated device comprising a die substrate, a die interconnection portion coupled to the die substrate, an inductor, and a shield structure. The shield structure comprises a shield frame and a plurality of shield branches coupled to the shield frame, wherein at least one shield branch from the plurality of shield branches comprises a repeating wave shape.

### FIELD

Various features relate to integrated devices with an inductors.

### BACKGROUND

A package may include a substrate and integrated devices. These components are coupled together to provide a package that may perform various functions. The performance of a package and its components may depend on how these components are configured together. One or more inductors may be affected by other nearby components and/or devices, which can affect the overall performance of the integrated device and/or the package. There is an ongoing need to provide integrated devices and/or packages with improved performances.

### SUMMARY

Various features relate to integrated devices with inductors.

One example provides a device that includes an integrated device and an inductor and a shield structure. The integrated device includes a die substrate and a die interconnection portion coupled to the die substrate. The shield structure includes a shield frame and a plurality of shield branches coupled to the shield frame, wherein at least one shield branch from the plurality of shield branches comprises a repeating wave shape.

Another example provides an integrated device comprising a die substrate, a die interconnection portion coupled to the die substrate, an inductor and a shield structure. The shield structure comprises a shield frame and a plurality of shield branches coupled to the shield frame, wherein at least one shield branch from the plurality of shield branches comprises a repeating wave shape.

Another example provides a method for fabricating an integrated device. The method provides a die substrate. The method forms a die interconnection portion that is coupled to the die substrate, wherein forming the die interconnection portion includes forming a plurality of die interconnects. The plurality of die interconnects includes an inductor and a shield structure. The shield structure includes a shield frame and a plurality of shield branches coupled to the shield frame, wherein at least one shield branch from the plurality of shield branches comprises a repeating wave shape.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a profile cross sectional view of an exemplary package that includes an integrated device and a package substrate

FIG. 2 illustrates an exemplary view of a patterned ground shield.

FIG. 3 illustrates an exemplary view of an inductor and a patterned ground shield nearby.

FIG. 4 illustrates an exemplary view of a patterned ground shield.

FIG. 5 illustrates an exemplary view of an inductor and a patterned ground shield nearby.

FIG. 6 illustrates an exemplary graph of the quality factor of an inductor with different ground shields.

FIG. 7 illustrates a profile cross sectional view of an exemplary integrated device that can include an inductor and a patterned ground shield.

FIG. 8 illustrates a profile cross sectional view of an exemplary package that includes an integrated device and a metallization portion, where the package can include an inductor and a patterned ground shield.

FIG. 9 illustrates an exemplary view of a patterned ground shield.

FIG. 10 illustrates an exemplary view of a patterned ground shield.

FIG. 11 illustrates an exemplary view of a patterned ground shield.

FIG. 12 illustrates an exemplary view of a patterned ground shield.

FIG. 13 illustrates an exemplary view of a patterned ground shield.

FIGS. 14A-14C illustrate an exemplary sequence for fabricating an integrated device.

FIG. 15 illustrates an exemplary flow diagram of a method for fabricating an integrated device.

FIGS. 16A-16D illustrate an exemplary sequence for fabricating a package.

FIG. 17 illustrates an exemplary flow diagram of a method for fabricating a package.

FIG. 18 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes an integrated device that includes a die substrate, a die interconnection portion coupled to the die substrate, an inductor, and a shield structure. The shield structure includes a shield frame and a plurality of shield branches coupled to the shield frame. At least one shield branch from the plurality of shield branches comprises a repeating wave shape. The shield structure may be configured as a patterned ground shield. The shield structure and the inductor may be located in the die interconnection portion of the integrated device. In some implementations, the shield structure may be located above the inductor. In some implementations, the shield structure may be located below the inductor. The use and the placement of the shield structure near an inductor helps improve the quality factor Q of the inductor. By improving the quality factor Q of the inductor through the use of the shield structure, an inductor with a minimum Q factor may be provided that is relatively smaller than another inductor without the shield structure. This allows smaller inductors (in terms of how much real estate they take up) to be formed while still providing minimum electrical performance for the integrated device and/or the package. Moreover, this allows the package and/or the integrated device to have a smaller sizes (e.g., footprint), without sacrificing and/or diminishing the performance of the package and/or the integrated device.

### Exemplary Package Comprising an Inductor and a Patterned Shield Structure

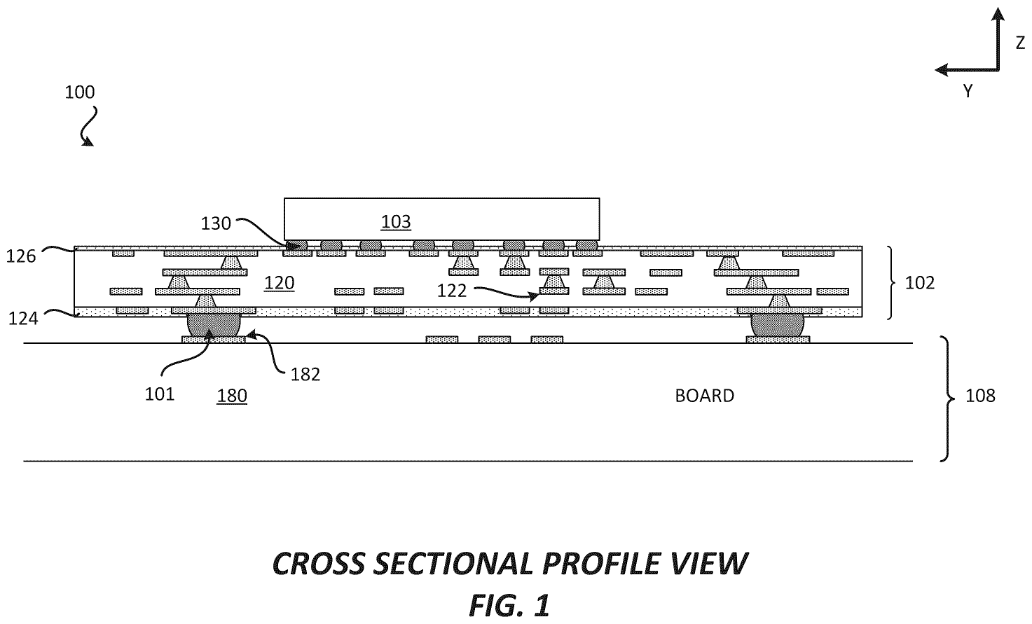

FIG. 1 illustrates a profile cross sectional view of a package 100 that includes a substrate 102 and an integrated device 103. The package 100 is coupled to a board 108 (e.g., printed circuit board) through a plurality of solder interconnects 101. The board 108 includes at least one board dielectric layer 180 and a plurality of board interconnects 182. The package 100 is coupled to the plurality of board interconnects 182 of the board 108 (e.g., printed circuit board) through the plurality of solder interconnects 101. The plurality of solder interconnects 101 may be coupled to board interconnects from the plurality of board interconnects 182.

The substrate 102 may be a package substrate. The substrate 102 includes a first surface (e.g., top surface) and a second surface (e.g., bottom surface). The substrate 102 includes at least one dielectric layer 120 (e.g., at least one substrate dielectric layer) and a plurality of interconnects 122 (e.g., plurality of substrate interconnects). The at least one dielectric layer 120 may include prepreg. In some implementations, the first surface of the substrate 102 includes a solder resist layer 126 and the second surface of the substrate 102 includes a solder resist layer 124. The substrate 102 may be a laminate substrate. Different implementations may use different types of substrates. Different implementations may use different materials for the at least one dielectric layer 120. The plurality of solder interconnects 101 may be coupled to interconnects from the plurality of interconnects 122.

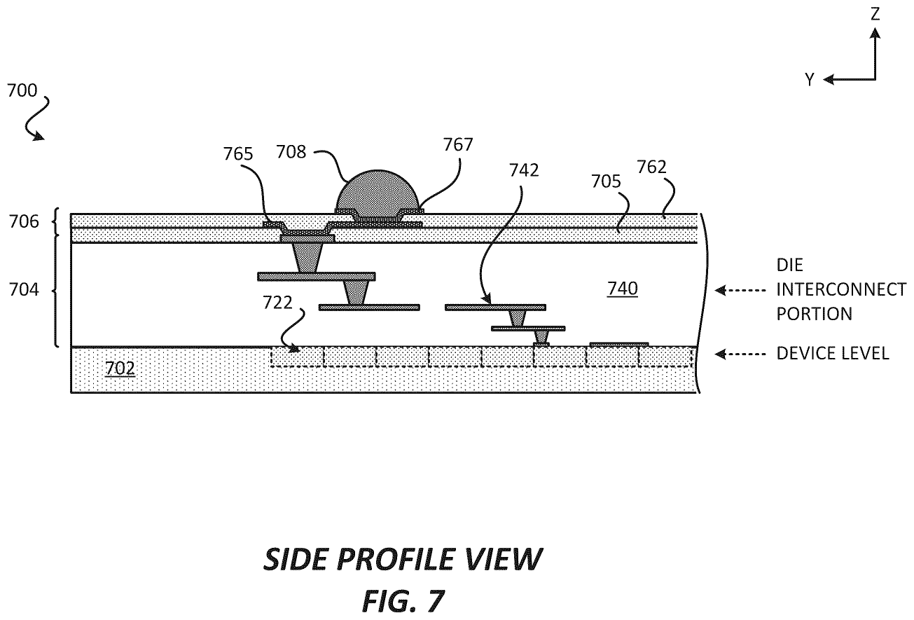

The integrated device 103 is coupled to the first surface (e.g., top surface) of the substrate 102 through a plurality of solder interconnects 130. For example, the integrated device 103 may be coupled to the substrate 102 through a plurality of pillar interconnects (not shown) and the plurality of solder interconnects 130. The plurality of solder interconnects 130 may be coupled to one or more interconnects from the plurality of interconnects 122. The integrated device 103 includes a front side and a back side. The front side of the integrated device 103 faces the substrate 102. Different implementations may use different types of integrated devices. An example of an integrated device is illustrated and described below in at least FIG. 7.

As will be further described below, an inductor and a shield structure may be implemented in the package 100. The shield structure may be a patterned ground shield. The shield structure may be configured to be electrically coupled to ground. The shield structure may include a shield frame and a plurality of shield branches coupled to the shield frame, where at least one shield branch from the plurality of shield branches includes a repeating wave shape. In some implementations, the at least one shield branch from the plurality of shield branches that includes a repeating wave shape comprises a repeating step wave shape. In some implementations, another shield branch from the plurality of shield branches comprises a repeating step wave shape. In some implementations, at least a portion of the shield frame defines an outer perimeter of the shield structure, and the plurality of shield branches may be a plurality of inner shield branches. In some implementations, the shield structure may be located vertically above the inductor. In some implementations, the shield structure may be located vertically below the inductor.

The placement of the shield structure near the inductor helps improve the quality factor Q of the inductor. By improving the quality factor Q of the inductor through the use of the shield structure, an inductor with a minimum Q factor may be provided that is relatively smaller than another inductor without the shield structure. This allows smaller inductors (in terms of how much real estate they take up) to be formed while still providing minimum electrical performance for the integrated device and/or the package. Moreover, this allows the package and/or the integrated device to have a smaller sizes (e.g., footprint), without sacrificing and/or diminishing the performance of the package and/or the integrated device.

In some implementations, the inductor and the shield structure may be implemented in the metal layers of the integrated device 103. In some implementations, the inductor and the shield structure may be implemented in the metal layers of the substrate 102. In some implementations, the inductor may be located in the integrated device 103 and the shield structure may be located in the substrate 102. In some implementations, the inductor may be located in the substrate 102 and the shield structure may be located in the integrated device 103.

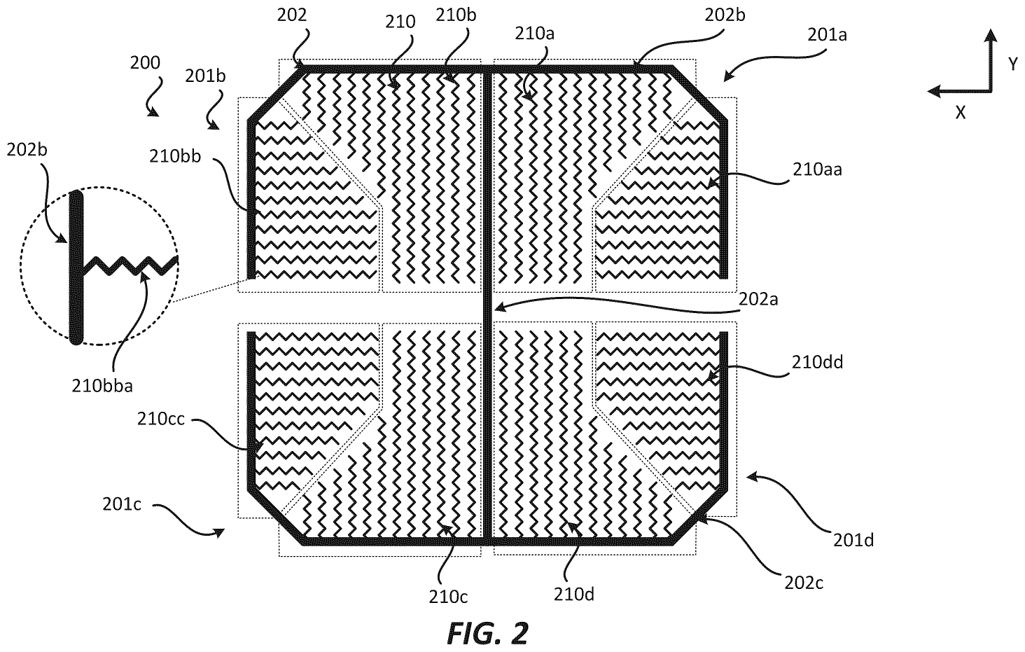

FIGS. 2-5 and 9-13 illustrate examples of different configurations of shield structure combinations that may be implemented in a package, an integrated device and/or a substrate (e.g., package substrate).

FIG. 2 illustrates a shield structure 200. The shield structure 200 may be configured to be electrically coupled to ground. The shield structure 200 may be a patterned ground shield. The patterned ground shield may be a patterned ground electromagnetic shield. The shield structure 200 may be implemented as interconnects on one or more metal layers. The shield structure 200 includes a shield frame 202 and a plurality of shield branches 210 coupled to the shield frame 202. The shield frame 202 includes a first shield frame 202a, a second shield frame 202b, a third shield frame 202c. Thus, the shield frame 202 may have more than one portion (e.g., shield frame portion). The shield frame 202 may have the shape of a double E, where a first E shape faces a second E shape. The first shield frame 202a is coupled to the second shield frame 202b. The first shield frame 202a is coupled to the third shield frame 202c.

The plurality of shield branches 210 include a first plurality of shield branches 210a, a second plurality of shield branches 210b, a third plurality of shield branches 210c, and a fourth plurality of shield branches 210d. The plurality of shield branches 210 may also include a first plurality of shield branches 210aa, a second plurality of shield branches 210bb, a third plurality of shield branches 210cc, and a fourth plurality of shield branches 210dd.

The shield structure 200 includes a first quadrant 201a, a second quadrant 201b, a third quadrant 201c and a fourth quadrant 201d. The boundary of the quadrants may be defined at least partially by the first shield frame 202a, the second shield frame 202b and the third shield frame 202c.

The first plurality of shield branches 210a and the first plurality of shield branches 210aa may be located in the first quadrant 201a of the shield structure 200. The second plurality of shield branches 210b and the second plurality of shield branches 210bb may be located in the second quadrant 201b of the shield structure 200. The third plurality of shield branches 210c and the third plurality of shield branches 210cc may be located in the third quadrant 201c of the shield structure 200. The fourth plurality of shield branches 210d and the fourth plurality of shield branches 210dd may be located in the fourth quadrant 201d of the shield structure 200.

The first plurality of shield branches 210a and the first plurality of shield branches 210aa may be coupled to the second shield frame 202b in the first quadrant 201a. The first plurality of shield branches 210a may extend (e.g., extend in a zigzag pattern) in a first direction that is along the first shield frame 202a. The first plurality of shield branches 210aa may extend (e.g., extend in a zigzag pattern) in a third direction that is perpendicular to the first shield frame 202a.

The second plurality of shield branches 210b and the second plurality of shield branches 210bb may be coupled to the second shield frame 202b in the second quadrant 201b. The second plurality of shield branches 210b may extend (e.g., extend in a zigzag pattern) in a first direction that is along the first shield frame 202a. The second plurality of shield branches 210bb may extend (e.g., extend in a zigzag pattern) in a fourth direction that is perpendicular to the first shield frame 202a. The fourth direction may be opposite to the third direction.

The third plurality of shield branches 210c and the third plurality of shield branches 210cc may be coupled to the third shield frame 202c in the third quadrant 201c. The third plurality of shield branches 210c may extend (e.g., extend in a zigzag pattern) in a second direction that is along the first shield frame 202a. The second direction may be opposite to the first direction. The third plurality of shield branches 210cc may extend (e.g., extend in a zigzag pattern) in a fourth direction that is perpendicular to the first shield frame 202a.

The fourth plurality of shield branches 210d and the fourth plurality of shield branches 210dd may be coupled to the third shield frame 202c in the fourth quadrant 201d. The fourth plurality of shield branches 210d may extend (e.g., extend in a zigzag pattern) in a second direction that is along the first shield frame 202a. The fourth plurality of shield branches 210dd may extend (e.g., extend in a zigzag pattern) in a third direction that is perpendicular to the first shield frame 202a.

In some implementations, one or more shield branches from the plurality of shield branches 210 may include a repeating zigzag shape. In some implementations, each shield branch from the plurality of shield branches 210 may include a repeating zigzag shape. In some implementations, one or more shield branches from the plurality of shield branches 210 may include a repeating wave shape. In some implementations, each shield branch from the plurality of shield branches 210 may include a repeating wave shape. In some implementations, one or more shield branches from the plurality of shield branches 210 may include a repeating step wave shape. In some implementations, each shield branch from the plurality of shield branches 210 may include a repeating step wave shape. In some implementations, one or more shield branches from the plurality of shield branches 210 may include a combination of a repeating wave shape and a repeating step wave shape. In some implementations, a repeating wave shape includes a shield branch that includes interconnects that change direction back and forth several times. In some implementations, a repeating step wave shape includes a shield branch that includes interconnects that changes direction by 90 degrees back and forth several times. For example, a shield branch may include an interconnect (e.g., shield interconnect) that turns left by 90 degrees, then turns right by 90 degrees, then left by 90 degrees, and then turns right by 90 degrees, in a repeating pattern. FIG. 2 illustrates a close up view of the shield branch 210bba, which is part of the second plurality of shield branches 210bb. The shield branch 210bba includes interconnects that change direction by 90 degrees back and forth.

As shown in FIG. 2, a shield branch from the plurality of shield branches 210 may include different numbers of repeating waves. The number of repeating waves may define the length of shield branch. In some implementations, a first shield branch from the plurality of shield branches 210 may have a first length, and second shield branch from the plurality of shield branches 210 may have a second length.

In some implementations, at least a portion of the shield frame 202 may define an outer perimeter of the shield structure 200. In some implementations, the plurality of shield branches 210 are a plurality of inner shield branches. At least a portion of the shield frame 202 may at least partially and laterally surround the plurality of shield branches 210. In some implementations, the shield structure 200 may be symmetrical in the X direction and/or the Y direction. For example, the shield structure 200 may be symmetrical when folded along the first shield frame 202a.

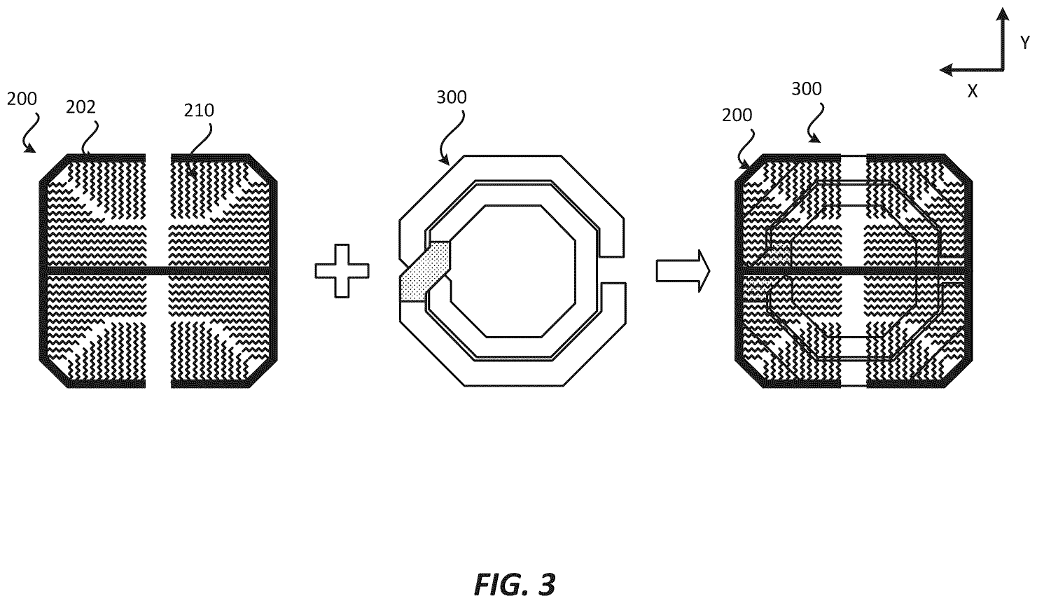

FIG. 3 illustrates how a combination of the shield structure 200 and an inductor 300 may vertically overlap in a package. The inductor 300 includes a plurality of windings and/or turns. The inductor 300 is merely an example of a design for an inductor. Different inductors may have different designs including different spirals, different numbers of turns, different windings, different crossings and/or different underpasses/overpasses. The number of turns in the spiral in the inductors shown in the disclosure are exemplary. Different implementations may have inductors with windings and/or spirals that have different numbers of turns.

The shield structure 200 is placed nearby the inductor 300. For example, the inductor 300 may be located on a metal layer (e.g., first metal layer) of an integrated device, and the shield structure 200 may located on another metal layer (e.g., second metal layer) of the integrated device. In some implementations, the shield structure 200 may be located above the inductor 300. In some implementations, the shield structure 200 may be located below the inductor 300.

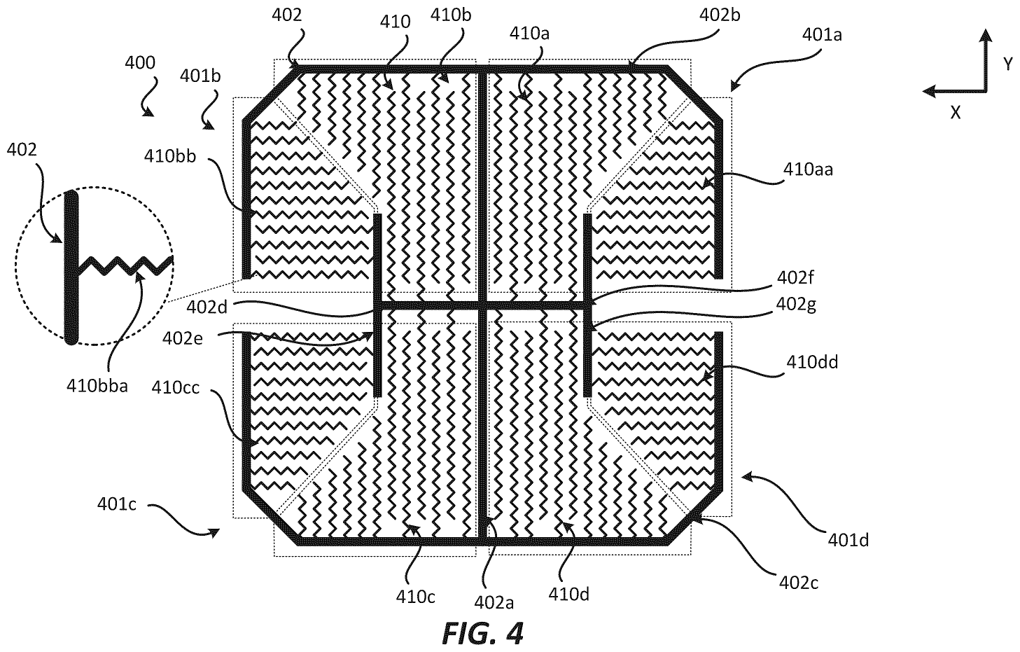

FIG. 4 illustrates a shield structure 400. The shield structure 400 may be configured to be electrically coupled to ground. The shield structure 400 may be implemented as interconnects on one or more metal layers. The shield structure 400 may be a patterned ground shield. The patterned ground shield may be a patterned ground electromagnetic shield. The shield structure 400 includes a shield frame 402 and a plurality of shield branches 410 coupled to the shield frame 402. The shield frame 402 includes a first shield frame 402a, a second shield frame 402b, a third shield frame 402c, a fourth shield frame 402d, a fifth shield frame 402e, a sixth shield frame 402f and a seventh shield frame 402g. Thus, the shield frame 402 may include several portions (e.g., shield frame portions). The shield frame 402 may have the shape of a double E and an H, where the a first E shape faces a second E shape, and where the H shape is located between the first E shape and the second E shape. The first shield frame 402a is coupled to the second shield frame 402b. The first shield frame 402a is coupled to the third shield frame 402c. The fourth shield frame 402d is coupled to the first shield frame 402a. The fifth shield frame 402e is coupled to the fourth shield frame 402d. The sixth shield frame 402f is coupled to the first shield frame 402a. The seventh shield frame 402g is coupled to the sixth shield frame 402f.

The plurality of shield branches 410 includes a first plurality of shield branches 410a, a second plurality of shield branches 410b, a third plurality of shield branches 410c, and a fourth plurality of shield branches 410d. The plurality of shield branches 410 may also include a first plurality of shield branches 410aa, a second plurality of shield branches 410bb, a third plurality of shield branches 410cc, and a fourth plurality of shield branches 410dd.

The shield structure 400 includes a first quadrant 401a, a second quadrant 401b, a third quadrant 401c and a fourth quadrant 401d. The boundary of the quadrants may be defined at least partially by the first shield frame 402a, the second shield frame 402b and the third shield frame 402c.

The first plurality of shield branches 410a and the first plurality of shield branches 410aa may be located in the first quadrant 401a of the shield structure 400. The second plurality of shield branches 410b and the second plurality of shield branches 410bb may be located in the second quadrant 401b of the shield structure 400. The third plurality of shield branches 410c and the third plurality of shield branches 410cc may be located in the third quadrant 401c of the shield structure 400. The fourth plurality of shield branches 410d and the fourth plurality of shield branches 410dd may be located in the fourth quadrant 401d of the shield structure 400.

The first plurality of shield branches 410a and the first plurality of shield branches 410aa may be coupled to (i) the second shield frame 402b, (ii) the sixth shield frame 402f and/or (iii) the seventh shield frame 402g, in the first quadrant 401a. The first plurality of shield branches 410a may extend (e.g., extend in a zigzag pattern) in a first direction that is along the first shield frame 402a. The first plurality of shield branches 410aa may extend (e.g., extend in a zigzag pattern) in a third direction that is perpendicular to the first shield frame 402a. The first plurality of shield branches 410a and the first plurality of shield branches 410aa may be interleaved shield branches.

The second plurality of shield branches 410b and the second plurality of shield branches 410bb may be coupled to (i) the second shield frame 402b, (ii) the fourth shield frame 402 and/or (iii) the fifth shield frame 402e, in the second quadrant 401b. The second plurality of shield branches 410b may extend (e.g., extend in a zigzag pattern) in a first direction that is along the first shield frame 402a. The second plurality of shield branches 410bb may extend (e.g., extend in a zigzag pattern) in a fourth direction that is perpendicular to the first shield frame 402a. The fourth direction may be opposite to the third direction. The second plurality of shield branches 410b and the second plurality of shield branches 410bb may be interleaved shield branches.

The third plurality of shield branches 410c and the third plurality of shield branches 410cc may be coupled to (i) the third shield frame 402c, (ii) the fourth shield frame 402 and/or (iii) the fifth shield frame 402e, in the third quadrant 401c. The third plurality of shield branches 410c may extend (e.g., extend in a zigzag pattern) in a second direction that is along the first shield frame 402a. The second direction may be opposite to the first direction. The third plurality of shield branches 410cc may extend (e.g., extend in a zigzag pattern) in a fourth direction that is perpendicular to the first shield frame 402a. The third plurality of shield branches 410c and the third plurality of shield branches 410cc may be interleaved shield branches.

The fourth plurality of shield branches 410d and the fourth plurality of shield branches 410dd may be coupled to (i) the third shield frame 402c, (ii) the sixth shield frame 402f and/or (iii) the seventh shield frame 402g, in the fourth quadrant 401d. The fourth plurality of shield branches 410d may extend (e.g., extend in a zigzag pattern) in a second direction that is along the first shield frame 402a. The fourth plurality of shield branches 410dd may extend (e.g., extend in a zigzag pattern) in a third direction that is perpendicular to the first shield frame 402a. The fourth plurality of shield branches 410d and the fourth plurality of shield branches 410dd may be interleaved shield branches.

In some implementations, one or more shield branches from the plurality of shield branches 410 may include a repeating zigzag shape. In some implementations, each shield branch from the plurality of shield branches 410 may include a repeating zigzag shape. In some implementations, one or more shield branches from the plurality of shield branches 410 may include a repeating wave shape. In some implementations, each shield branch from the plurality of shield branches 410 may include a repeating wave shape. In some implementations, one or more shield branches from the plurality of shield branches 410 may include a repeating step wave shape. In some implementations, each shield branch from the plurality of shield branches 410 may include a repeating step wave shape. In some implementations, one or more shield branches from the plurality of shield branches 410 may include a combination of a repeating wave shape and a repeating step wave shape. In some implementations, a repeating wave shape includes a shield branch that includes interconnects that change direction back and forth several times. In some implementations, a repeating step wave shape includes a shield branch that includes interconnects that changes direction by 90 degrees back and forth several times. For example, a shield branch may include an interconnect (e.g., shield interconnect) that turns left by 90 degrees, then turns right by 90 degrees, then left by 90 degrees, and then turns right by 90 degrees, in a repeating pattern. FIG. 4 illustrates a close up view of the shield branch 410bba, which is part of the second plurality of shield branches 410bb. The shield branch 410bba includes interconnects that change direction by 90 degrees back and forth.

As shown in FIG. 4, a shield branch from the plurality of shield branches 410 may include different numbers of repeating waves. The number of repeating waves may define the length of shield branch. In some implementations, a first shield branch from the plurality of shield branches 410 may have a first length, and second shield branch from the plurality of shield branches 410 may have a second length.

In some implementations, at least a portion of the shield frame 402 may define an outer perimeter of the shield structure 400. In some implementations, the plurality of shield branches 410 are a plurality of inner shield branches. Portions of the shield frame 402 may at least partially and laterally surround the plurality of shield branches 410. In some implementations, the shield structure 400 may be symmetrical in the X direction and/or the Y direction. For example, the shield structure 400 may be symmetrical when folded along the first shield frame 402a. In another example, the shield structure 400 may be symmetrical when folded along the fourth shield frame 402d.

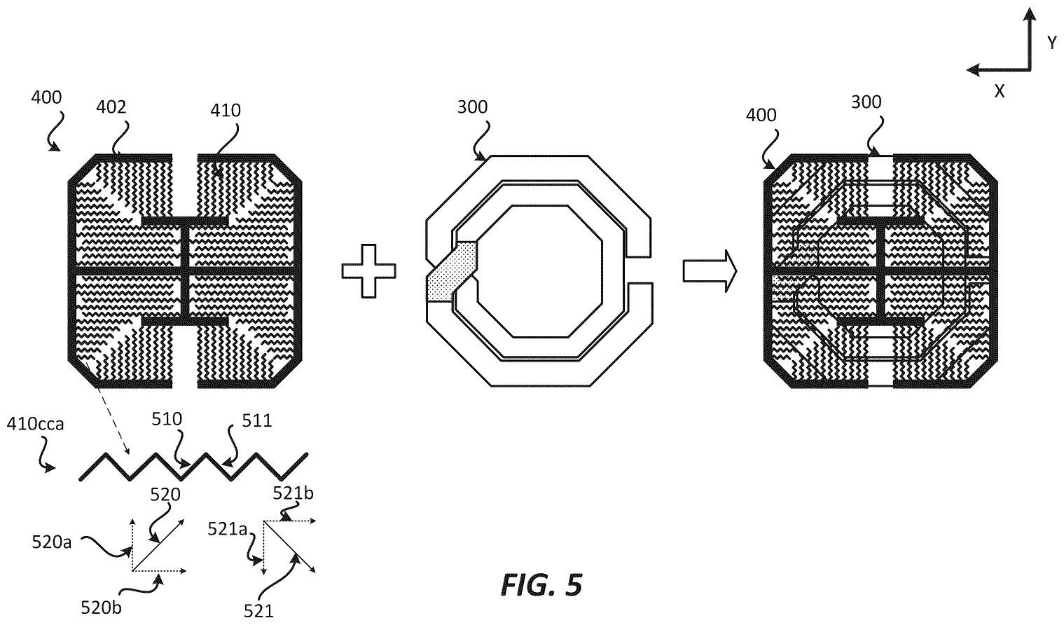

FIG. 5 illustrates how a combination of the shield structure 400 and an inductor 300 may vertically overlap in a package. The inductor 300 includes a plurality of windings and/or turns. The inductor 300 is merely an example of a design for an inductor. Different inductors may have different designs including different spirals, different numbers of turns, different windings, different crossings and/or different underpasses/overpasses. The number of turns in the spiral in the inductors shown in the disclosure are exemplary. Different implementations may have inductors with windings and/or spirals that have different numbers of turns.

The shield structure 400 is placed nearby the inductor 300. For example, the inductor 300 may be located on a metal layer of an integrated device, and the shield structure 400 may located on another metal layer of the integrated device. In some implementations, the shield structure 400 may be located above the inductor 300. In some implementations, the shield structure 400 may be located below the inductor 300.

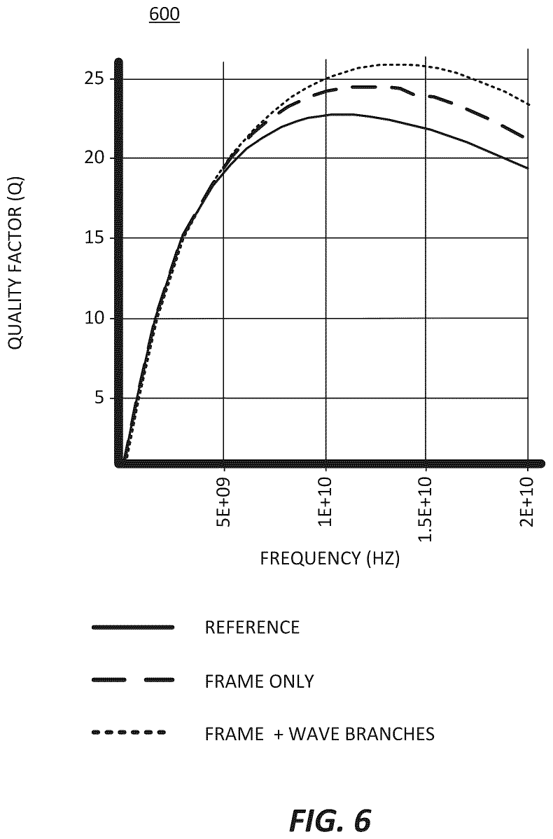

FIG. 6 illustrates an exemplary graph 600 that shows the quality factor (Q) of various inductors across various frequencies, including a reference inductor, an inductor in combination with a shield structure with only a shield frame, and an inductor in combination with a shield structure that includes a shield frame and a plurality of shield branches. FIG. 6 illustrates that the use of a shield structure with a shield frame and a plurality of shield branches helps improve the quality factor of the inductor.

An inductor that is placed near the shield structure may induce a current in the shield structure, which may create eddy currents that can couple back to the inductor, which in turns can lower the quality factor of the nearby inductor. However, the design of the plurality of shield branches of the shield structure can cause cancellation and/or reduction in such induced current by a nearby inductor. For example, the back and forth change (e.g., zigzagging back and forth) in directions of the plurality of shield branches may cause any induced current within a segment of the plurality of shield branches to at least partially cancel out with another segment of the plurality of shield branches. For example, a first segment of the plurality of shield branches may be aligned in a first direction and a second segment of the plurality of shield branches may be aligned in a second direction that is different from the first direction. So a magnetic field from the inductor may induce currents in different directions for the first segment and the second segment of the plurality of shield branches, where the first segment and the second segment are nearby or adjacent to each other. These currents in different directions may at least partially offset and/or at least partially cancel each other out in the plurality of shield branches. Reducing, minimizing and/or canceling out the induced currents helps provide a nearby inductor that has an improved quality factor Q.

Referring back to FIG. 5, which illustrates the shield structure 400 that includes a shield branch 410cca. The shield branch 410cca includes a first segment 510 and a second segment 511 The first segment 510 is aligned in a first direction and the second segment 511 is aligned in a second direction. The second direction may be orthogonal to the first direction. In this example, an inductor may induce a current 520 in the first segment 510 in the first direction, and a current 521 in the second segment 511 in the second direction. The first current 520 may have a Y direction component current 520a and an X direction component current 520b. The second current 521 may have a Y direction component current 521a and an X direction component current 521b. As shown in FIG. 5, the Y direction component current 520a and the Y direction component current 521a are opposite to each other and may cancel each other out. It is noted that the use of the plurality of shield branches arranged in different directions helps reduce, minimize and/or cancel induced currents by a nearby inductor, resulting with an inductor with an improved quality factor.

As mentioned above, the placement of the shield structure near the inductor helps improve the quality factor Q of the inductor. By improving the quality factor Q of the inductor through the use of the shield structure, an inductor with a minimum Q factor may be provided that is relatively smaller than another inductor without the shield structure. This allows smaller inductors (in terms of how much real estate they take up) to be formed while still providing minimum electrical performance for the integrated device and/or the package. Moreover, this allows the package and/or the integrated device to have a smaller sizes (e.g., footprint), without sacrificing and/or diminishing the performance of the package and/or the integrated device.

It is note that the repeating zigzag pattern and/or repeating wave pattern are described in the disclosure as changing direction by about 90 degrees. However, different implementations may use repeating patterns that change direction by different degrees. In some implementations, the repeating patterns may change direction with different variations of degrees. For example, the interconnect of a shield branch may change by 45 degrees (left or right), and then change by 90 degrees (left or right) and then change by 30 degrees (left or right).

FIG. 7 illustrates a cross sectional profile view of an integrated device 700. The integrated device 700 may represent the integrated device 103 of FIG. 1. The integrated device 700 includes a die substrate 702, an interconnection portion 704 (e.g., die interconnection portion), a metallization portion 706. A plurality of solder interconnects 708 may be coupled to the metallization portion 706.

The die substrate 702 may include silicon (Si). A plurality of cells (e.g., logic cells) and/or a plurality of transistors (not shown) may be formed in and/or over the die substrate 702. The plurality of cells (e.g., logic cells) and/or a plurality of transistors (not shown) may be part of the device level 722 of the integrated device 700. Different implementations may use different types of transistors, such as a field effect transistor (FET), planar FET, finFET, and a gate all around FET. In some implementations, a front end of line (FEOL) process may be used to fabricate the plurality of cells (e.g., logic cells) and/or transistors in and/or over the die substrate 702. Although not shown, the die substrate 702 may include through substrate vias. Moreover, one or more metal layers (not shown and which may form back side interconnects) may be coupled to the back side of the die substrate 702. These back side interconnects may be coupled to the through substrate vias. The interconnection portion 704 is located over and coupled to the die substrate 702. The interconnection portion 704 may be coupled to the plurality of cells and/or transistors located in and/or over the die substrate 702. The interconnection portion 704 (e.g., die interconnection portion) may include at least one dielectric layer 740 (e.g., die dielectric layer) and a plurality of die interconnects 742. The plurality of die interconnects 742 may be coupled to the plurality of cells and/or transistors. In some implementations, a back end of line (BEOL) process may be used to fabricate the interconnection portion 704. The interconnection portion 704 may include a passivation layer 705. The passivation layer 705 may be located over the at least one dielectric layer 740.

The metallization portion 706 is coupled to the interconnection portion 704. The metallization portion 706 includes a plurality of metallization interconnects 765, a plurality of under bump metallization interconnects 767 and a dielectric layer 762. The plurality of metallization interconnects 765 are coupled to the plurality of die interconnects 742. The plurality of metallization interconnects 765 may include a plurality of redistribution interconnects. The plurality of under bump metallization interconnects 767 are coupled to the plurality of metallization interconnects 765. The plurality of solder interconnects 708 are coupled to the plurality of under bump metallization interconnects 767. In some implementations, there may be a plurality of pillar interconnects (not shown) between the plurality of solder interconnects 708 and the plurality of under bump metallization interconnects 767.

The metallization portion 706 may be optional. In such instances, the plurality of solder interconnects 708 may be coupled to the plurality of die interconnects 742 (e.g., directly coupled to pad interconnects from the plurality of die interconnects 742).

In some implementations, a shield structure (e.g., 200, 400) may be located in the interconnection portion 704 and/or the metallization portion 706 of the integrated device 700. In some implementations, one or more inductors (e.g., 300) may be located in the interconnection portion 704 and/or the metallization portion 706 of the integrated device 700. In some implementations, the shield structure (e.g., 200, 400) may be located above the inductor (e.g., 300). In some implementations, the shield structure (e.g., 200, 400) may be located below the inductor (e.g., 300).

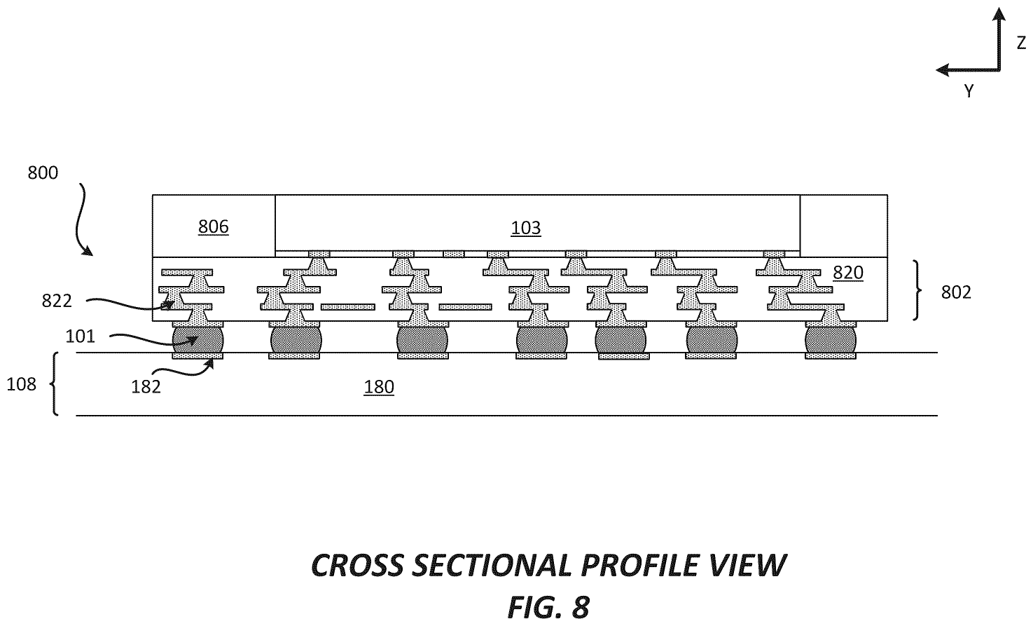

FIG. 8 illustrates a package 800 that includes an integrated device 103, a metallization portion 802 and an encapsulation layer 806. The metallization portion 802 includes at least one dielectric layer 820 and a plurality of metallization interconnects 822. The metallization portion 802 may include a redistribution portion. The package 800 is coupled to the board 108 through a plurality of solder interconnects 101.

In some implementations, a shield structure (e.g., 200, 400) may be located in the integrated device 103 and/or the metallization portion 802 of the package 800. In some implementations, an inductor (e.g., 300) may be located in the integrated device 103 and/or the metallization portion 802 of the package 800. In some implementations, the shield structure (e.g., 200, 400) may be located above the inductor (e.g., 300). In some implementations, the shield structure (e.g., 200, 400) may be located below the inductor (e.g., 300).

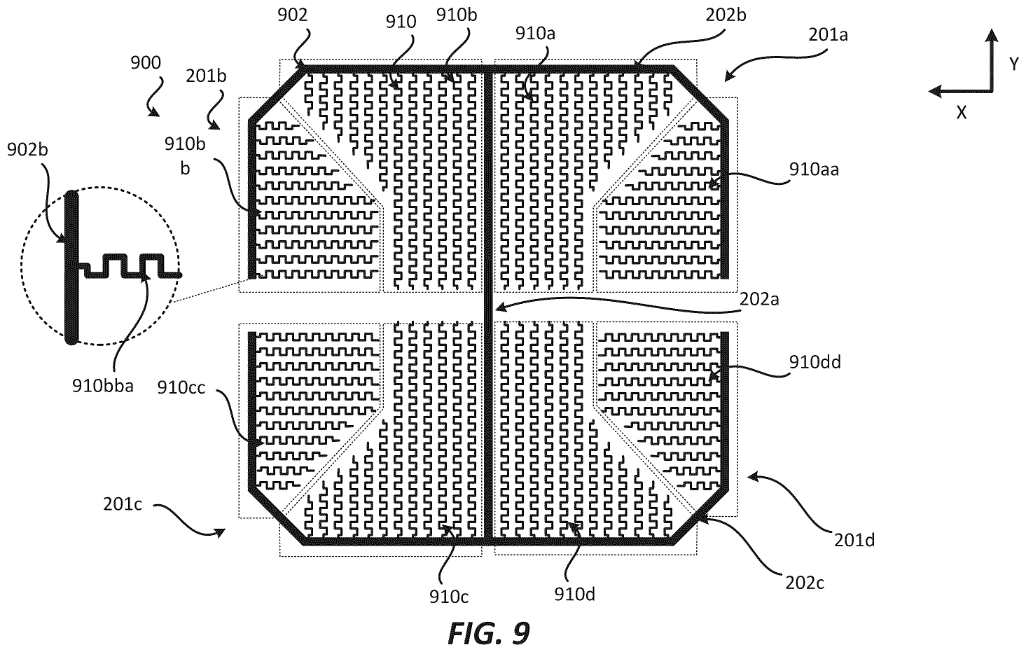

As mentioned above, different implementations may have different designs and/or configurations for inductors. FIGS. 9-13 illustrate other examples of shield structures that may be implemented in an integrated device and/or a package.

FIG. 9 illustrates a shield structure 900. The shield structure 900 may be configured to be electrically coupled to ground. The shield structure 900 may be a patterned ground shield. The patterned ground shield may be a patterned ground electromagnetic shield. The shield structure 900 is similar to the shield structure 200. However, the shield structure 900 may include shield branches with different designs. The shield structure 900 includes a shield frame 202 and a plurality of shield branches 910 coupled to the shield frame 202. The shield frame 202 includes a first shield frame 202a, a second shield frame 202b, a third shield frame 202c. The shield frame 202 may have the shape of a double E, where the a first E shape faces a second E shape. The first shield frame 202a is coupled to the second shield frame 202b. The first shield frame 202a is coupled to the third shield frame 202c.

The plurality of shield branches 910 includes a first plurality of shield branches 910a, a second plurality of shield branches 910b, a third plurality of shield branches 910c, and a fourth plurality of shield branches 910d. The plurality of shield branches 910 may also include a first plurality of shield branches 910aa, a second plurality of shield branches 910bb, a third plurality of shield branches 910cc, and a fourth plurality of shield branches 910dd.

The shield structure 900 includes a first quadrant 201a, a second quadrant 201b, a third quadrant 201c and a fourth quadrant 201d. The boundary of the quadrants may be defined at least partially by the first shield frame 202a, the second shield frame 202b and the third shield frame 202c.

The first plurality of shield branches 910a and the first plurality of shield branches 910aa may be located in the first quadrant 201a of the shield structure 900. The second plurality of shield branches 910b and the second plurality of shield branches 910bb may be located in the second quadrant 201b of the shield structure 900. The third plurality of shield branches 910c and the third plurality of shield branches 910cc may be located in the third quadrant 201c of the shield structure 900. The fourth plurality of shield branches 910d and the fourth plurality of shield branches 910dd may be located in the fourth quadrant 201d of the shield structure 900.

The first plurality of shield branches 910a and the first plurality of shield branches 910aa may be coupled to the second shield frame 202b in the first quadrant 201a. The first plurality of shield branches 910a may extend (e.g., extend in a zigzag pattern) in a first direction that is along the first shield frame 202a. The first plurality of shield branches 910aa may extend (e.g., extend in a zigzag pattern) in a third direction that is perpendicular to the first shield frame 202a.

The second plurality of shield branches 910b and the second plurality of shield branches 910bb may be coupled to the second shield frame 202b in the second quadrant 201b. The second plurality of shield branches 910b may extend (e.g., extend in a zigzag pattern) in a first direction that is along the first shield frame 202a. The second plurality of shield branches 910bb may extend (e.g., extend in a zigzag pattern) in a fourth direction that is perpendicular to the first shield frame 202a. The fourth direction may be opposite to the third direction.

The third plurality of shield branches 910c and the third plurality of shield branches 910cc may be coupled to the third shield frame 202c in the third quadrant 201c. The third plurality of shield branches 910c may extend (e.g., extend in a zigzag pattern) in a second direction that is along the first shield frame 202a. The second direction may be opposite to the first direction. The third plurality of shield branches 910cc may extend (e.g., extend in a zigzag pattern) in a fourth direction that is perpendicular to the first shield frame 202a.

The fourth plurality of shield branches 910d and the fourth plurality of shield branches 910dd may be coupled to the third shield frame 202c in the fourth quadrant 201d. The fourth plurality of shield branches 910d may extend (e.g., extend in a zigzag pattern) in a second direction that is along the first shield frame 202a. The fourth plurality of shield branches 910dd may extend (e.g., extend in a zigzag pattern) in a third direction that is perpendicular to the first shield frame 202a.

In some implementations, one or more shield branches from the plurality of shield branches 910 may include a repeating zigzag shape. In some implementations, each shield branch from the plurality of shield branches 910 may include a repeating zigzag shape. In some implementations, one or more shield branches from the plurality of shield branches 910 may include a repeating step wave shape. In some implementations, each shield branch from the plurality of shield branches 910 may include a repeating step wave shape. In some implementations, one or more shield branches from the plurality of shield branches 910 may include a combination of a repeating wave shape and a repeating step wave shape. In some implementations, a repeating wave shape includes a shield branch that includes interconnects that change direction back and forth several times. In some implementations, a repeating step wave shape includes a shield branch that includes interconnects that changes direction by 90 degrees back and forth several times. For example, a shield branch may include an interconnect (e.g., shield interconnect) that turns left by 90 degrees, then turns left by 90 degrees, then turn right by 90 degrees, and then turns right by 90 degrees, in a repeating pattern. FIG. 9 illustrates a close up view of the shield branch 910bba, which is part of the second plurality of shield branches 910bb. The shield branch 910bba includes interconnects that change direction by 90 degrees back and forth.

As shown in FIG. 9, a shield branch from the plurality of shield branches 910 may include different numbers of repeating waves. The number of repeating waves may define the length of shield branch. In some implementations, a first shield branch from the plurality of shield branches 910 may have a first length, and second shield branch from the plurality of shield branches 910 may have a second length.

In some implementations, at least a portion of the shield frame 202 may define an outer perimeter of the shield structure 900. In some implementations, the plurality of shield branches 910 are a plurality of inner shield branches. The plurality of shield branches 910 may be laterally surrounded by at least a portion of the shield frame 202. In some implementations, the shield structure 900 may be symmetrical in the X direction and/or the Y direction. For example, the shield structure 900 may be symmetrical when folded along the first shield frame 202a.

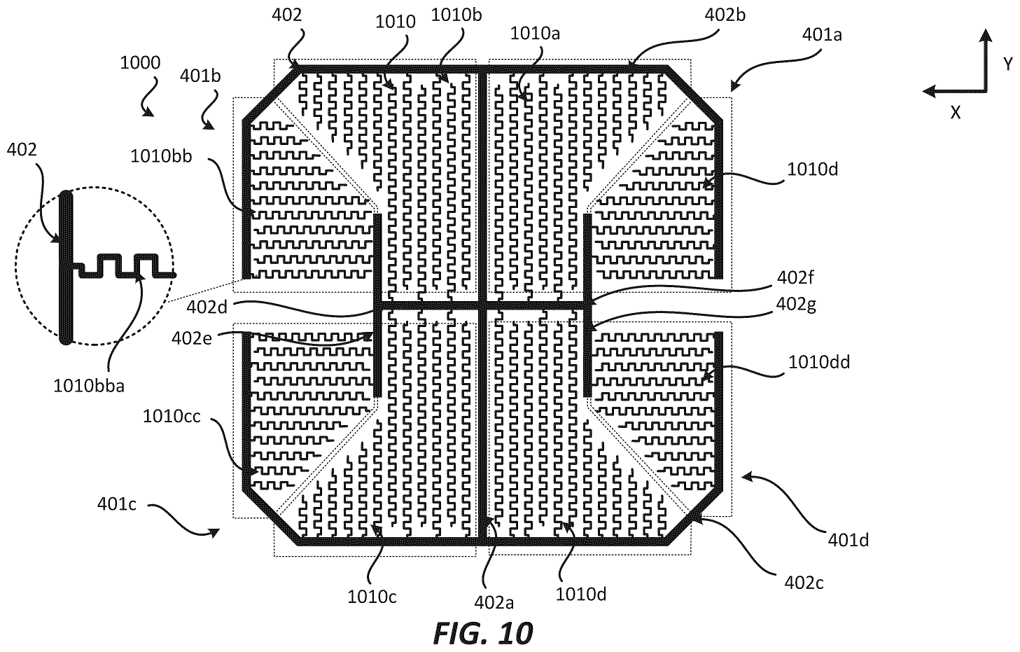

FIG. 10 illustrates a shield structure 1000. The shield structure 1000 may be configured to be electrically coupled to ground. The shield structure 1000 may be a patterned ground shield. The patterned ground shield may be a patterned ground electromagnetic shield. The shield structure 1000 includes a shield frame 402 and a plurality of shield branches 1010 coupled to the shield frame 402. The shield frame 402 includes a first shield frame 402a, a second shield frame 402b, a third shield frame 402c. a fourth shield frame 402d, a fifth shield frame 402c, a sixth shield frame 402f and a seventh shield frame 402g. The shield frame 402 may have the shape of a double E and an H, where the a first E shape faces a second E shape, and where the H shape is located between the first E shape and the second E shape. The first shield frame 402a is coupled to the second shield frame 402b. The first shield frame 402a is coupled to the third shield frame 402c. The fourth shield frame 402d is coupled to the first shield frame 402a. The fifth shield frame 402e is coupled to the fourth shield frame 402d. The sixth shield frame 402f is coupled to the first shield frame 402a. The seventh shield frame 402g is coupled to the sixth shield frame 402f.

The plurality of shield branches 1010 includes a first plurality of shield branches 1010a, a second plurality of shield branches 1010b, a third plurality of shield branches 1010c, and a fourth plurality of shield branches 1010d. The plurality of shield branches 1010 may also include a first plurality of shield branches 1010aa, a second plurality of shield branches 1010bb, a third plurality of shield branches 1010cc, and a fourth plurality of shield branches 1010dd.

The shield structure 1000 includes a first quadrant 401a, a second quadrant 401b, a third quadrant 401c and a fourth quadrant 401d. The boundary of the quadrants may be defined at least partially by the first shield frame 402a, the second shield frame 402b and the third shield frame 402c.

The first plurality of shield branches 1010a and the first plurality of shield branches 1010aa may be located in the first quadrant 401a of the shield structure 1000. The second plurality of shield branches 1010b and the second plurality of shield branches 1010bb may be located in the second quadrant 401b of the shield structure 1000. The third plurality of shield branches 1010c and the third plurality of shield branches 1010cc may be located in the third quadrant 401c of the shield structure 1000. The fourth plurality of shield branches 1010d and the fourth plurality of shield branches 1010dd may be located in the fourth quadrant 401d of the shield structure 1000.

The first plurality of shield branches 1010a and the first plurality of shield branches 1010aa may be coupled to (i) the second shield frame 402b, (ii) the sixth shield frame 402f and/or (iii) the seventh shield frame 402g, in the first quadrant 401a. The first plurality of shield branches 1010a may extend (e.g., extend in a zigzag pattern) in a first direction that is along the first shield frame 402a. The first plurality of shield branches 1010aa may extend (e.g., extend in a zigzag pattern) in a third direction that is perpendicular to the first shield frame 402a. The first plurality of shield branches 1010a and the first plurality of shield branches 1010aa may be interleaved shield branches.

The second plurality of shield branches 1010b and the second plurality of shield branches 1010bb may be coupled to (i) the second shield frame 402b, (ii) the fourth shield frame 402 and/or (iii) the fifth shield frame 402e, in the second quadrant 401b. The second plurality of shield branches 1010b may extend (e.g., extend in a zigzag pattern) in a first direction that is along the first shield frame 402a. The second plurality of shield branches 1010bb may extend (e.g., extend in a zigzag pattern) in a fourth direction that is perpendicular to the first shield frame 402a. The fourth direction may be opposite to the third direction. The second plurality of shield branches 1010b and the second plurality of shield branches 1010bb may be interleaved shield branches.

The third plurality of shield branches 1010c and the third plurality of shield branches 1010cc may be coupled to (i) the third shield frame 402c, (ii) the fourth shield frame 402 and/or (iii) the fifth shield frame 402c, in the third quadrant 401c. The third plurality of shield branches 1010c may extend (e.g., extend in a zigzag pattern) in a second direction that is along the first shield frame 402a. The second direction may be opposite to the first direction. The third plurality of shield branches 1010cc may extend (e.g., extend in a zigzag pattern) in a fourth direction that is perpendicular to the first shield frame 402a. The third plurality of shield branches 1010c and the third plurality of shield branches 1010cc may be interleaved shield branches.

The fourth plurality of shield branches 1010d and the fourth plurality of shield branches 1010dd may be coupled to (i) the third shield frame 402c, (ii) the sixth shield frame 402f and/or (iii) the seventh shield frame 402g. in the fourth quadrant 401d. The fourth plurality of shield branches 1010d may extend (e.g., extend in a zigzag pattern) in a second direction that is along the first shield frame 402a. The fourth plurality of shield branches 1010dd may extend (e.g., extend in a zigzag pattern) in a third direction that is perpendicular to the first shield frame 402a. The fourth plurality of shield branches 1010d and the fourth plurality of shield branches 1010dd may be interleaved shield branches.

In some implementations, one or more shield branches from the plurality of shield branches 1010 may include a repeating step zigzag shape. In some implementations, each shield branch from the plurality of shield branches 1010 may include a repeating step zigzag shape. In some implementations, one or more shield branches from the plurality of shield branches 1010 may include a repeating step wave shape. In some implementations, each shield branch from the plurality of shield branches 1010 may include a repeating step wave shape. In some implementations, a repeating step wave shape includes a shield branch that includes interconnects that change direction back and forth several times. In some implementations, a repeating step wave shape includes a shield branch that includes interconnects that changes direction by 90 degrees back and forth several times. For example, a shield branch may include an interconnect (e.g., shield interconnect) that turns left by 90 degrees, then turns left by 90 degrees, then turns right by 90 degrees, and then turns right by 90 degrees, in a repeating pattern. FIG. 10 illustrates a close up view of the shield branch 1010bba, which is part of the second plurality of shield branches 1010bb. The shield branch 1010bba includes interconnects that change direction by 90 degrees back and forth.

As shown in FIG. 10, a shield branch from the plurality of shield branches 1010 may include different numbers of repeating waves. The number of repeating waves may define the length of shield branch. In some implementations, a first shield branch from the plurality of shield branches 410 may have a first length, and second shield branch from the plurality of shield branches 410 may have a second length.

In some implementations, at least a portion of the shield frame 402 may define an outer perimeter of the shield structure 1000. In some implementations, the plurality of shield branches 410 are a plurality of inner shield branches. The plurality of shield branches 1010 may be laterally surrounded by at least a portion of the shield frame 402. In some implementations, the shield structure 1000 may be symmetrical in the X direction and/or the Y direction. For example, the shield structure 1000 may be symmetrical when folded along the first shield frame 402a. In another example, the shield structure 1000 may be symmetrical when folded along the fourth shield frame 402d.

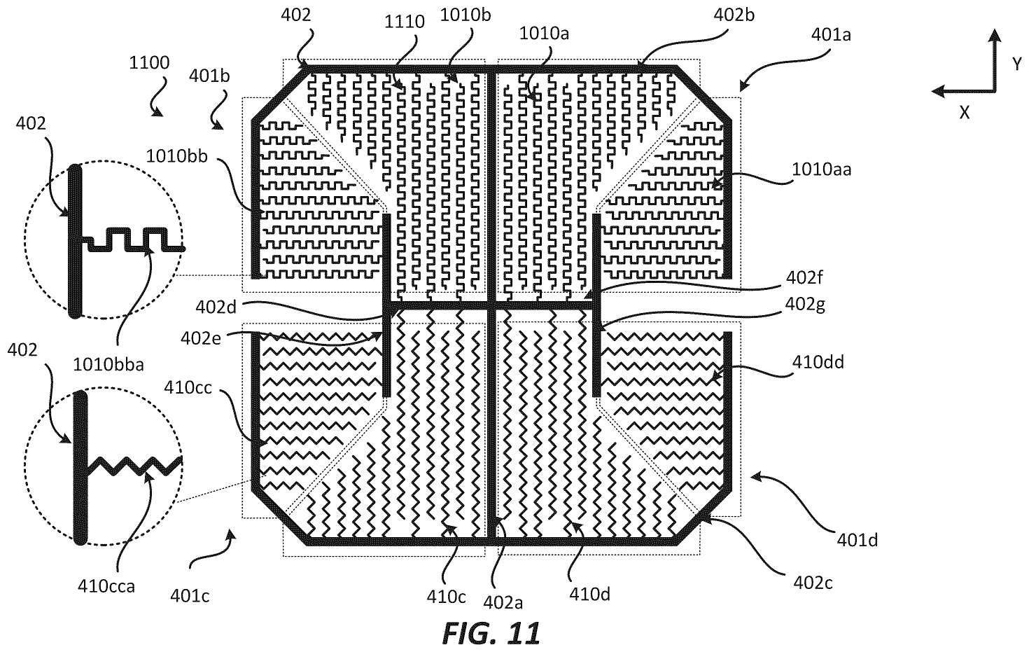

FIG. 11 illustrates a shield structure 1100. The shield structure 1100 may be configured to be electrically coupled to ground. The shield structure 1100 may be a patterned ground shield. The patterned ground shield may be a patterned ground electromagnetic shield. The shield structure 1100 may be a combination of the shield structure 400 and the shield structure 1000. As will be further described below, some of the shield branches may have different designs.

The shield structure 1100 includes a shield frame 402 and a plurality of shield branches 1010 coupled to the shield frame 402. The shield frame 402 includes a first shield frame 402a, a second shield frame 402b, a third shield frame 402c, a fourth shield frame 402d, a fifth shield frame 402e, a sixth shield frame 402f and a seventh shield frame 402g. The shield frame 402 may have the shape of a double E and an H, where the a first E shape faces a second E shape, and where the H shape is located between the first E shape and the second E shape. The first shield frame 402a is coupled to the second shield frame 402b. The first shield frame 402a is coupled to the third shield frame 402c. The fourth shield frame 402d is coupled to the first shield frame 402a. The fifth shield frame 402e is coupled to the fourth shield frame 402d. The sixth shield frame 402f is coupled to the first shield frame 402a. The seventh shield frame 402g is coupled to the sixth shield frame 402f.

The plurality of shield branches 1110 includes a first plurality of shield branches 1010a, a second plurality of shield branches 1010b, a third plurality of shield branches 410c, and a fourth plurality of shield branches 410d. The plurality of shield branches 1110 may also include a first plurality of shield branches 1010aa, a second plurality of shield branches 1010bb, a third plurality of shield branches 410cc, and a fourth plurality of shield branches 410dd.

The shield structure 1100 includes a first quadrant 401a, a second quadrant 401b, a third quadrant 401c and a fourth quadrant 401d. The boundary of the quadrants may be defined at least partially by the first shield frame 402a, the second shield frame 402b and the third shield frame 402c.

The first plurality of shield branches 1010a and the first plurality of shield branches 1010aa may be located in the first quadrant 401a of the shield structure 1100. The second plurality of shield branches 1010b and the second plurality of shield branches 1010bb may be located in the second quadrant 401b of the shield structure 1100. The third plurality of shield branches 410c and the third plurality of shield branches 410cc may be located in the third quadrant 401c of the shield structure 1100. The fourth plurality of shield branches 410d and the fourth plurality of shield branches 410dd may be located in the fourth quadrant 401d of the shield structure 1100.

The first plurality of shield branches 1010a and the first plurality of shield branches 1010aa may be coupled to (i) the second shield frame 402b, (ii) the sixth shield frame 402f and/or (iii) the seventh shield frame 402g, in the first quadrant 401a. The first plurality of shield branches 1010a may extend (e.g., extend in a zigzag pattern) in a first direction that is along the first shield frame 402a. The first plurality of shield branches 1010aa may extend (e.g., extend in a zigzag pattern) in a third direction that is perpendicular to the first shield frame 402a. The first plurality of shield branches 1010a and the first plurality of shield branches 1010aa may be interleaved shield branches.

The second plurality of shield branches 1010b and the second plurality of shield branches 1010bb may be coupled to (i) the second shield frame 402b, (ii) the fourth shield frame 402 and/or (iii) the fifth shield frame 402e, in the second quadrant 401b. The second plurality of shield branches 1010b may extend (e.g., extend in a zigzag pattern) in a first direction that is along the first shield frame 402a. The second plurality of shield branches 1010bb may extend (e.g., extend in a zigzag pattern) in a fourth direction that is perpendicular to the first shield frame 402a. The fourth direction may be opposite to the third direction. The second plurality of shield branches 1010b and the second plurality of shield branches 1010bb may be interleaved shield branches.

The third plurality of shield branches 410c and the third plurality of shield branches 410cc may be coupled to (i) the third shield frame 402c, (ii) the fourth shield frame 402 and/or (iii) the fifth shield frame 402e, in the third quadrant 401c. The third plurality of shield branches 410c may extend (e.g., extend in a zigzag pattern) in a second direction that is along the first shield frame 402a. The second direction may be opposite to the first direction. The third plurality of shield branches 410cc may extend (e.g., extend in a zigzag pattern) in a fourth direction that is perpendicular to the first shield frame 402a. The third plurality of shield branches 410c and the third plurality of shield branches 410cc may be interleaved shield branches.

The fourth plurality of shield branches 410d and the fourth plurality of shield branches 410dd may be coupled to (i) the third shield frame 402c, (ii) the sixth shield frame 402f and/or (iii) the seventh shield frame 402g, in the fourth quadrant 401d. The fourth plurality of shield branches 410d may extend (e.g., extend in a zigzag pattern) in a second direction that is along the first shield frame 402a. The fourth plurality of shield branches 410dd may extend (e.g., extend in a zigzag pattern) in a third direction that is perpendicular to the first shield frame 402a. The fourth plurality of shield branches 410d and the fourth plurality of shield branches 410dd may be interleaved shield branches.

FIG. 11 illustrates a close up view of the shield branch 1010bba, which is part of the second plurality of shield branches 1010bb. The shield branch 1010bba includes interconnects that change direction by 90 degrees back and forth. FIG. 11 also illustrates a close up view of the shield branch 410cca, which is part of the third plurality of shield branches 410cc. The shield branch 410ca includes interconnects that change direction by 90 degrees back and forth

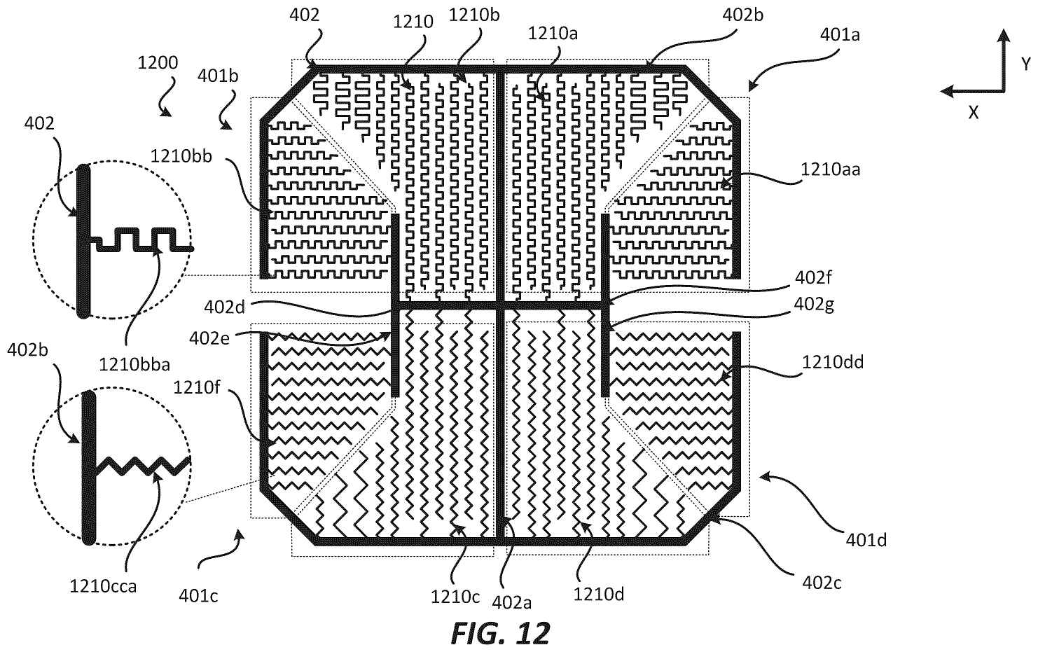

FIG. 12 illustrates a shield structure 1200. The shield structure 1200 may be configured to be electrically coupled to ground. The shield structure 1200 may be a patterned ground shield. The patterned ground shield may be a patterned ground electromagnetic shield. The shield structure 1200 may be similar to the shield structure 1100. As will be further described below, some of the shield branches may have different sizes, designs and/or shapes.

The shield structure 1200 includes a shield frame 402 and a plurality of shield branches 1210 coupled to the shield frame 402. The shield frame 402 includes a first shield frame 402a, a second shield frame 402b, a third shield frame 402c, a fourth shield frame 402d, a fifth shield frame 402e, a sixth shield frame 402f and a seventh shield frame 402g. The shield frame 402 may have the shape of a double E and an H, where the a first E shape faces a second E shape, and where the H shape is located between the first E shape and the second E shape. The first shield frame 402a is coupled to the second shield frame 402b. The first shield frame 402a is coupled to the third shield frame 402c. The fourth shield frame 402d is coupled to the first shield frame 402a. The fifth shield frame 402e is coupled to the fourth shield frame 402d. The sixth shield frame 402f is coupled to the first shield frame 402a. The seventh shield frame 402g is coupled to the sixth shield frame 402f.

The plurality of shield branches 1210 include a first plurality of shield branches 1210a, a second plurality of shield branches 1210b, a third plurality of shield branches 1210c, and a fourth plurality of shield branches 1210d. The plurality of shield branches 1210 may also include a first plurality of shield branches 1210aa, a second plurality of shield branches 1210bb, a third plurality of shield branches 1210cc, and a fourth plurality of shield branches 1210dd.

The shield structure 1200 includes a first quadrant 401a, a second quadrant 401b, a third quadrant 401c and a fourth quadrant 401d. The boundary of the quadrants may be defined at least partially by the first shield frame 402a, the second shield frame 402b and the third shield frame 402c.

The first plurality of shield branches 1210a and the first plurality of shield branches 1210aa may be located in the first quadrant 401a of the shield structure 1200. The second plurality of shield branches 1210b and the second plurality of shield branches 1210bb may be located in the second quadrant 401b of the shield structure 1200. The third plurality of shield branches 1210c and the third plurality of shield branches 1210cc may be located in the third quadrant 401c of the shield structure 1200. The fourth plurality of shield branches 1210d and the fourth plurality of shield branches 1210dd may be located in the fourth quadrant 401d of the shield structure 1200.

FIG. 12 illustrates that some of the shield branches may have different amplitudes from other shield branches. For example, some shield branches from the first plurality of shield branches 1210a may have different amplitudes from shield branches from the first plurality of shield branches 1210aa. In another example, some shield branches from the first plurality of shield branches 1210d may have different amplitudes from shield branches from the first plurality of shield branches 1210dd.

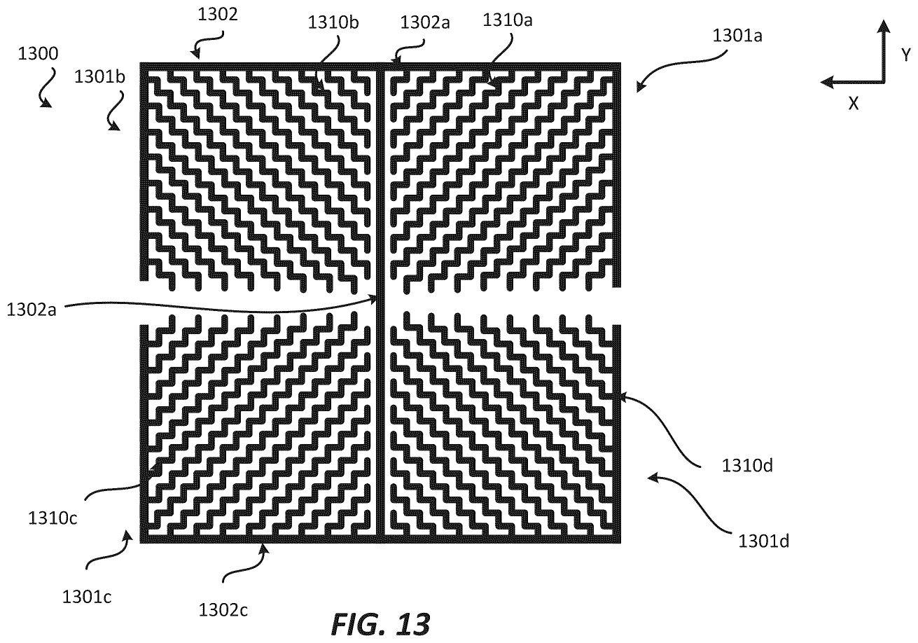

FIG. 13 illustrates a shield structure 1300. The shield structure 1300 may be configured to be electrically coupled to ground. The shield structure 1300 may be a patterned ground shield. The patterned ground shield may be a patterned ground electromagnetic shield.

The shield structure 1300 includes a shield frame 1302 and a plurality of shield branches 1310 coupled to the shield frame 1302. The shield frame 1302 includes a first shield frame 1302a, a second shield frame 1302b and a third shield frame 1302c. The shield frame 402 may have the shape of a double E, where the a first E shape faces a second E shape. The first shield frame 1302a is coupled to the second shield frame 1302b. The first shield frame 1302a is coupled to the third shield frame 1302c.

The plurality of shield branches 1310 includes a first plurality of shield branches 1310a, second plurality of shield branches 1310b, the third plurality of shield branches 1310c, and a fourth plurality of shield branches 1310d.

The shield structure 1300 includes a first quadrant 1301a, a second quadrant 1301b, a third quadrant 1301c and a fourth quadrant 1301d. The boundary of the quadrants may be defined at least partially by the first shield frame 1302a, the second shield frame 1302b and the third shield frame 1302c.

The first plurality of shield branches 1310a may be located in the first quadrant 1301a of the shield structure 1300. The second plurality of shield branches 1310b may be located in the second quadrant 1301b of the shield structure 1300. The third plurality of shield branches 1310c may be located in the third quadrant 1301c of the shield structure 1300. The fourth plurality of shield branches 1310d may be located in the fourth quadrant 1301d of the shield structure 1300.

The first plurality of shield branches 1310a extends in a first diagonal direction in a zigzag pattern and/or repeating wave pattern. The second plurality of shield branches 1310b extends in a second diagonal direction in a zigzag pattern and/or repeating wave pattern. The third plurality of shield branches 1310c extends in a third diagonal direction in a zigzag pattern and/or repeating wave pattern. The fourth plurality of shield branches 1310d extends in a fourth diagonal direction in a zigzag pattern and/or repeating wave pattern. The diagonal direction of the zigzag pattern and/or repeating wave pattern may be with respect to the X-Y plane.

In some implementations, one or more shield branches from the plurality of shield branches 1310 may include a repeating zigzag shape. In some implementations, each shield branch from the plurality of shield branches 1310 may include a repeating zigzag shape. In some implementations, one or more shield branches from the plurality of shield branches 1310 may include a repeating wave shape. In some implementations, each shield branch from the plurality of shield branches 1310 may include a repeating wave shape. In some implementations, one or more shield branches from the plurality of shield branches 1310 may include a repeating step wave shape. In some implementations, each shield branch from the plurality of shield branches 1310 may include a repeating step wave shape. In some implementations, one or more shield branches from the plurality of shield branches 1310 may include a combination of a repeating wave shape and a repeating step wave shape.

An integrated device (e.g., 103) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device (e.g., 103, 700, 800) may include at least one electronic circuit (e.g., first electronic circuit, second electronic circuit, etc. . . . ). An integrated device may include transistors. An integrated device may be an example of an electrical component and/or electrical device. In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes.

FIGS. 9-13 illustrate examples of shield structures and/or patterned ground shields that may be implemented in different parts of a package. As mentioned above, the shield structures of FIGS. 9-13 may be implemented in an integrated device, a substrate and/or a board. For example, the shield structures of FIGS. 9-13 may be implemented in various parts of the integrated device of FIG. 7 and/or the various parts of the package of FIG. 8. Any of the shield structures described in the disclosure may have different designs, including different shapes, different sizes, different shield frames, different shield branches, different number of shield branches and/or different amplitudes for the shield branches. The designs of the shield structures are not limited to what is shown in the figures of the disclosure.

### Exemplary Sequence for Fabricating an Integrated Device

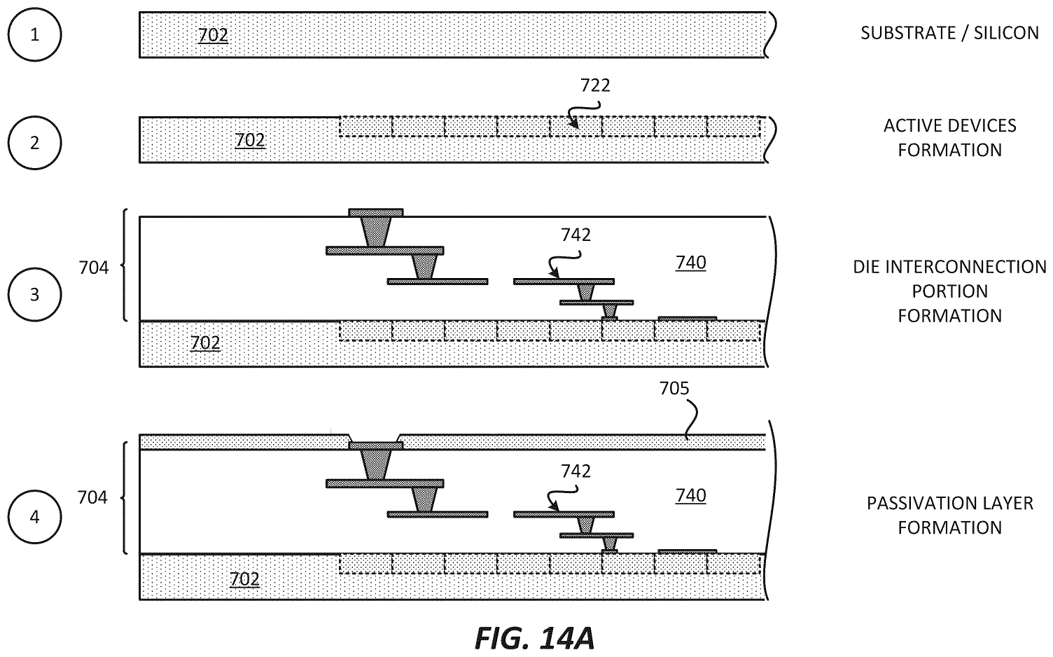

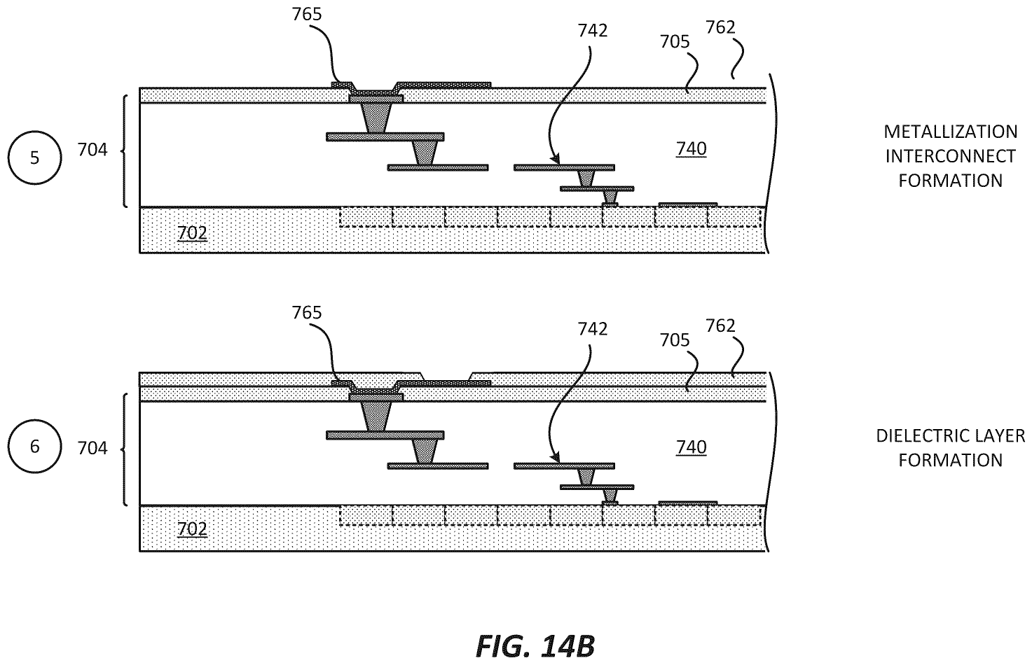

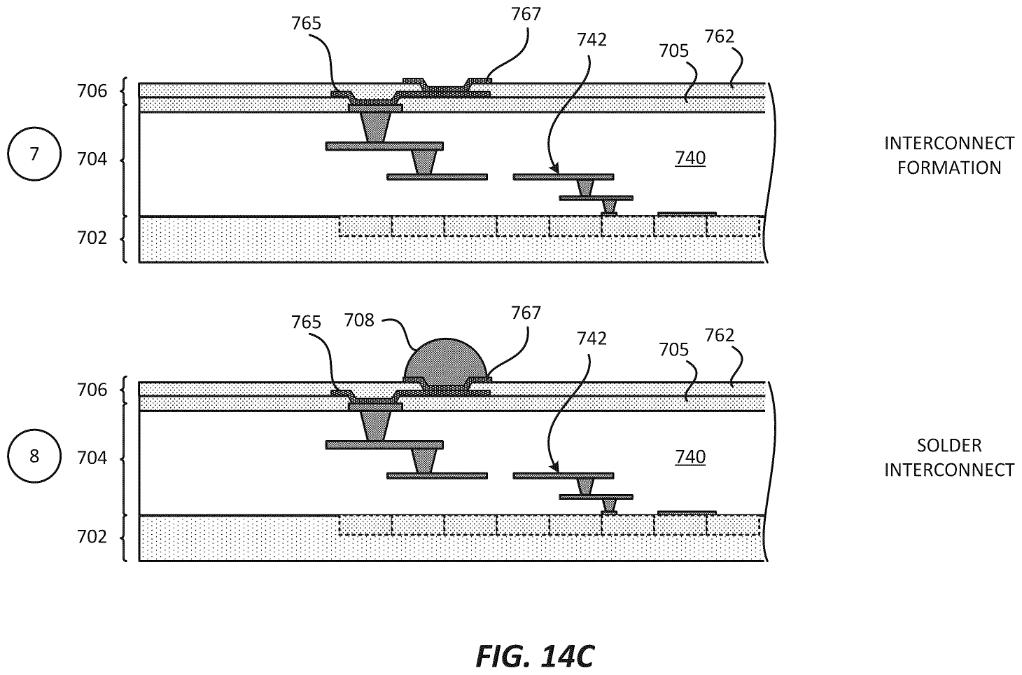

FIGS. 14A-14C illustrate an exemplary sequence for providing or fabricating an integrated device. In some implementations, the sequence of FIGS. 14A-14C may be used to provide or fabricate the integrated device 700 of FIG. 7, or any of the integrated devices described in the disclosure.

It should be noted that the sequence of FIGS. 14A-14C may combine one or more stages in order to simplify and/or clarify the sequence for providing or fabricating the integrated device. In some implementations, the order of the processes may be changed or modified. In some implementations, one or more of processes may be replaced or substituted without departing from the scope of the disclosure. The sequence of FIGS. 14A-14C may be used to fabricate one integrated device or several integrated devices at a time (as part of a wafer).

Stage 1, as shown in FIG. 14A illustrates a state after a die substrate 702 is provided. The die substrate 702 may include a wafer. The die substrate 702 may include silicon.

Stage 2 illustrates a state after a plurality of active devices are formed in and over the die substrate 702. The active devices may be part of the device level 722 of an integrated device. The plurality of active devices may include a plurality of cells (e.g., logic cells) and/or a plurality of transistors (not shown) that may be formed in and/or over the die substrate 702. The plurality of cells (e.g., logic cells) and/or a plurality of transistors (not shown) may be part of the device level 722 of the integrated device 700. Different implementations may use different types of transistors, such as a field effect transistor (FET), planar FET, finFET, and a gate all around FET. In some implementations, a front end of line (FEOL) process may be used to fabricate the plurality of cells (e.g., logic cells) and/or transistors in and/or over the die substrate 702.

Stage 3 illustrates a state after an interconnection portion 704 is formed. The interconnection portion 704 is located over and coupled to the die substrate 702. The interconnection portion 704 may be coupled to the plurality of cells and/or transistors located in and/or over the die substrate 702. The interconnection portion 704 (e.g., die interconnection portion) may include at least one dielectric layer 740 (e.g., die dielectric layer) and a plurality of die interconnects 742. The plurality of die interconnects 742 may be coupled to the plurality of cells and/or transistors. In some implementations, a back end of line (BEOL) process may be used to fabricate the interconnection portion 704.

Stage 4 illustrates a state after a passivation layer 705 is formed. The passivation layer 705 may be a dielectric layer. The passivation layer 705 may be considered part of the interconnection portion 704. The passivation layer 705 may be located over the at least one dielectric layer 740. A deposition and/or lamination process may be used to form the passivation layer 705.

Stage 5, as shown in FIG. 14B, illustrates a state after a plurality of metallization interconnects 765 are formed. The plurality of metallization interconnects 765 are coupled to a die interconnect from the plurality of die interconnects 742. A plating process may be used to form the plurality of metallization interconnects 765.

Stage 6 illustrates a state after a dielectric layer 762 is formed. The dielectric layer 762 may be located over the passivation layer 705 and the plurality of metallization interconnects 765. A deposition and/or lamination process may be used to form the dielectric layer 762.

Stage 7, as shown in FIG. 14C, illustrates a state after a plurality of under bump metallization interconnects 767 are formed. The plurality of under bump metallization interconnects 767 are coupled to the plurality of metallization interconnects 765. A plating process may be used to form the plurality of under bump metallization interconnects 767. In some implementations, the plurality of metallization interconnects 765, the dielectric layer 762 and the plurality of under bump metallization interconnects 767 may be part of a metallization portion 706 of an integrated device.

Stage 8 illustrates a state after a plurality of solder interconnects 708 are coupled to the plurality of under bump metallization interconnects 767. A solder reflow process may be used to form the plurality of solder interconnects 708. The metallization portion 706 may be optional. In such instances, the plurality of solder interconnects 708 may be coupled to the plurality of die interconnects 742 (e.g., directly coupled to pad interconnects from the plurality of die interconnects 742).

### Exemplary Flow Diagram of a Method for Fabricating an Integrated Device

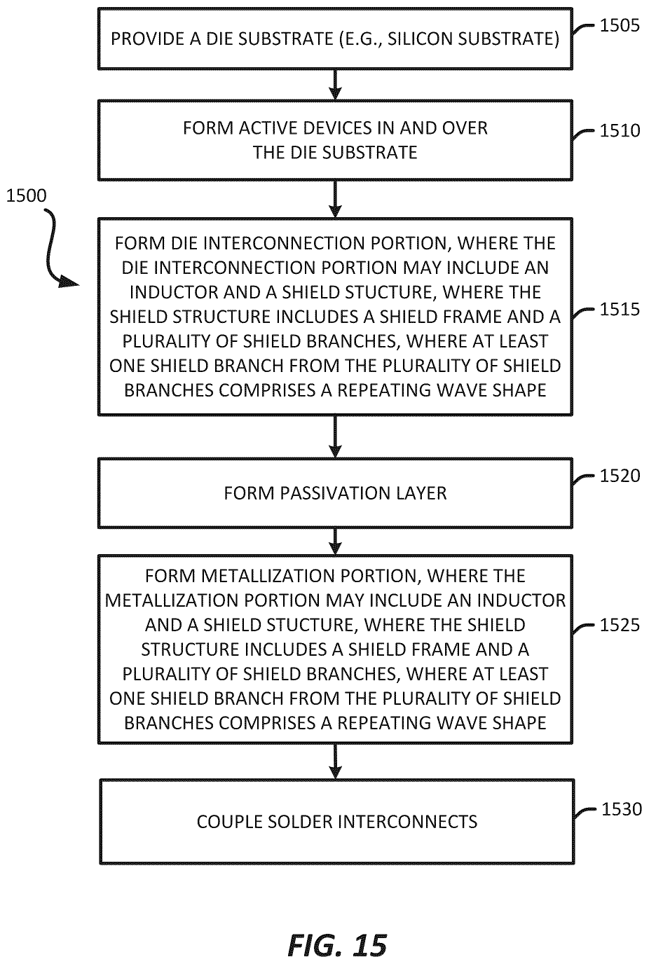

In some implementations, fabricating an integrated device includes several processes. FIG. 15 illustrates an exemplary flow diagram of a method 1500 for providing or fabricating an integrated device. In some implementations, the method 1500 of FIG. 15 may be used to provide or fabricate any of the integrated devices of the disclosure. For example, the method 1500 of FIG. 15 may be used to fabricate the integrated device 700.

It should be noted that the method 1500 of FIG. 15 may combine one or more processes in order to simplify and/or clarify the method for providing or fabricating a package. In some implementations, the order of the processes may be changed or modified. In some implementations, one or more of processes may be replaced or substituted without departing from the scope of the disclosure. The method 1500 of FIG. 15 may be used to fabricate one integrated device or several integrated devices at a time (as part of a wafer).

The method provides (at 1505) a die substrate. Stage 1 of FIG. 14A, illustrates and describes an example of a die substrate 702 that is provided. The die substrate 702 may include a wafer. The die substrate 702 may include silicon.

The method forms (at 1510) active devices in the and over the die substrate. Stage 2 of FIG. 14A, illustrates and describes an example of a plurality of active devices that are formed in and over the die substrate 702. The active devices may be part of the device level 722 of an integrated device. The plurality of active devices may include a plurality of cells (e.g., logic cells) and/or a plurality of transistors (not shown) that may be formed in and/or over the die substrate 702. The plurality of cells (e.g., logic cells) and/or a plurality of transistors (not shown) may be part of the device level 722 of the integrated device 700. Different implementations may use different types of transistors, such as a field effect transistor (FET), planar FET, finFET, and a gate all around FET. In some implementations, a front end of line (FEOL) process may be used to fabricate the plurality of cells (e.g., logic cells) and/or transistors in and/or over the die substrate 702.

The method forms (at 1515) a die interconnection portion that is coupled to the die substrate. Forming the die interconnection portion includes forming at least one dielectric layer and a plurality of die interconnects. Stage 3 of FIG. 14A, illustrates and describes an example of an interconnection portion 704 is formed. The interconnection portion 704 is located over and coupled to the die substrate 702. The interconnection portion 704 may be coupled to the plurality of cells and/or transistors located in and/or over the die substrate 702. The interconnection portion 704 (e.g., die interconnection portion) may include at least one dielectric layer 740 (e.g., die dielectric layer) and a plurality of die interconnects 742. The plurality of die interconnects 742 may be coupled to the plurality of cells and/or transistors. In some implementations, a back end of line (BEOL) process may be used to fabricate the interconnection portion 704. In some implementations, an inductor and/or a shield structure that includes a shield frame and a plurality of shield branches coupled to the shield frame, where at least one shield branch from the plurality of shield branches comprises a repeating wave shape, may be formed in the interconnection portion 704.

The method forms (at 1520) a passivation layer. Stage 4 of FIG. 14A, illustrates and describes an example of a passivation layer 705 that is formed. The passivation layer 705 may be a dielectric layer. The passivation layer 705 may be considered part of the interconnection portion 704. The passivation layer 705 may be located over the at least one dielectric layer 740. A deposition and/or lamination process may be used to form the passivation layer 705.

The method forms (at 1525) a metallization portion that is coupled to the die interconnection portion. Forming the metallization portion may include forming a plurality of metallization interconnects, at least one dielectric layer and/or a plurality of under bump metallization interconnects. Stage 5 of FIG. 14B, illustrates and describes an example of a plurality of metallization interconnects 765 that are formed. The plurality of metallization interconnects 765 are coupled to a die interconnect from the plurality of die interconnects 742. A plating process may be used to form the plurality of metallization interconnects 765. Stage 6 of FIG. 14B, illustrates and describes an example of a dielectric layer 762 that is formed. The dielectric layer 762 may be located over the passivation layer 705 and the plurality of metallization interconnects 765. A deposition and/or lamination process may be used to form the dielectric layer 762. Stage 7 of FIG. 14C, illustrates and describes an example of a plurality of under bump metallization interconnects 767 that are formed. The plurality of under bump metallization interconnects 767 are coupled to the plurality of metallization interconnects 765. A plating process may be used to form the plurality of under bump metallization interconnects 767. In some implementations, the plurality of metallization interconnects 765, the dielectric layer 762 and the plurality of under bump metallization interconnects 767 may be part of a metallization portion 706 of an integrated device. In some implementations, an inductor and/or a shield structure that includes a shield frame and a plurality of shield branches coupled to the shield frame, where at least one shield branch from the plurality of shield branches comprises a repeating wave shape, may be formed in the metallization portion 706.

The method couples (at 1530) a plurality of solder interconnects to a metallization portion. Stage 8 of FIG. 14C, illustrates and describes an example of a plurality of solder interconnects 708 that are coupled to the plurality of under bump metallization interconnects 767. A solder reflow process may be used to form the plurality of solder interconnects 708. The metallization portion 706 may be optional. In such instances, the plurality of solder interconnects 708 may be coupled to the plurality of die interconnects 742 (e.g., directly coupled to pad interconnects from the plurality of die interconnects 742).

### Exemplary Sequence for Fabricating a Package Comprising an Integrated Device and a Metallization Portion

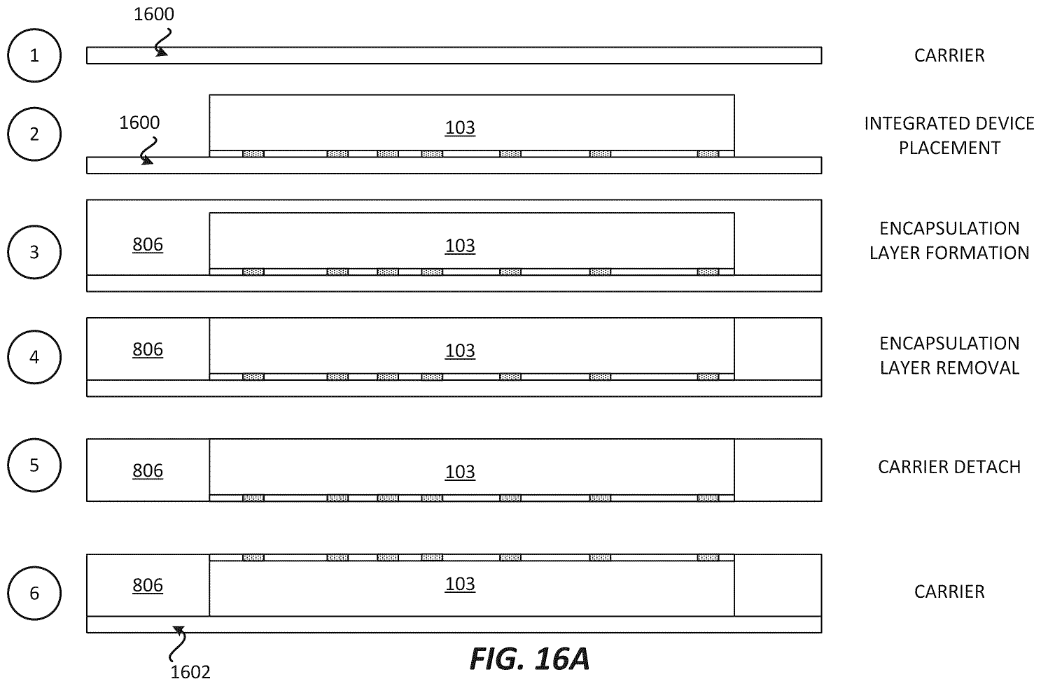

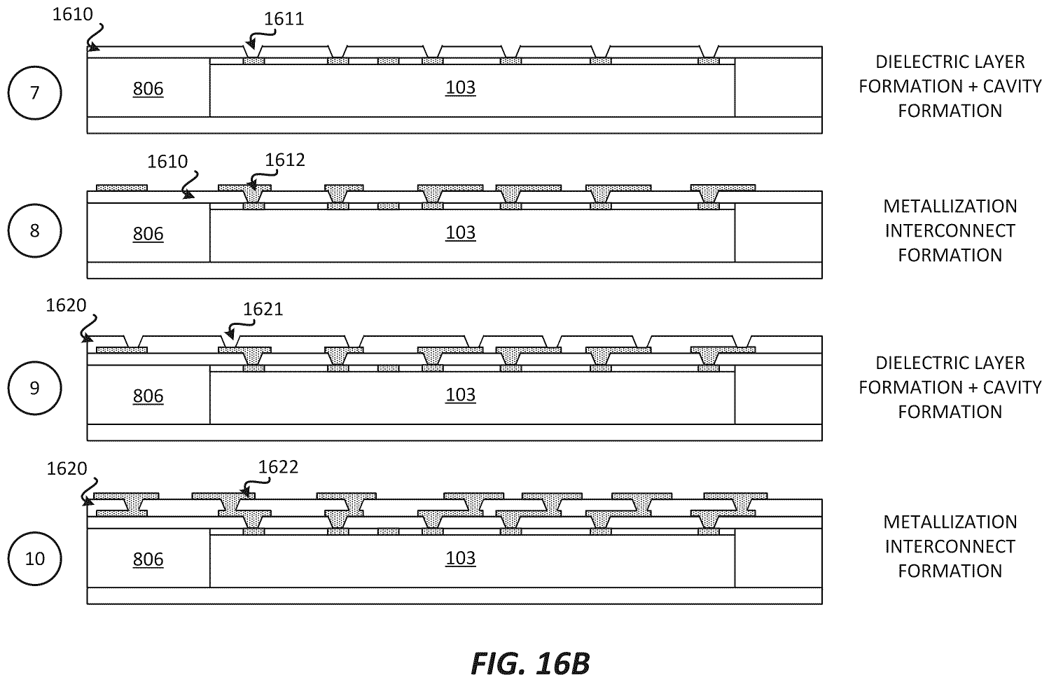

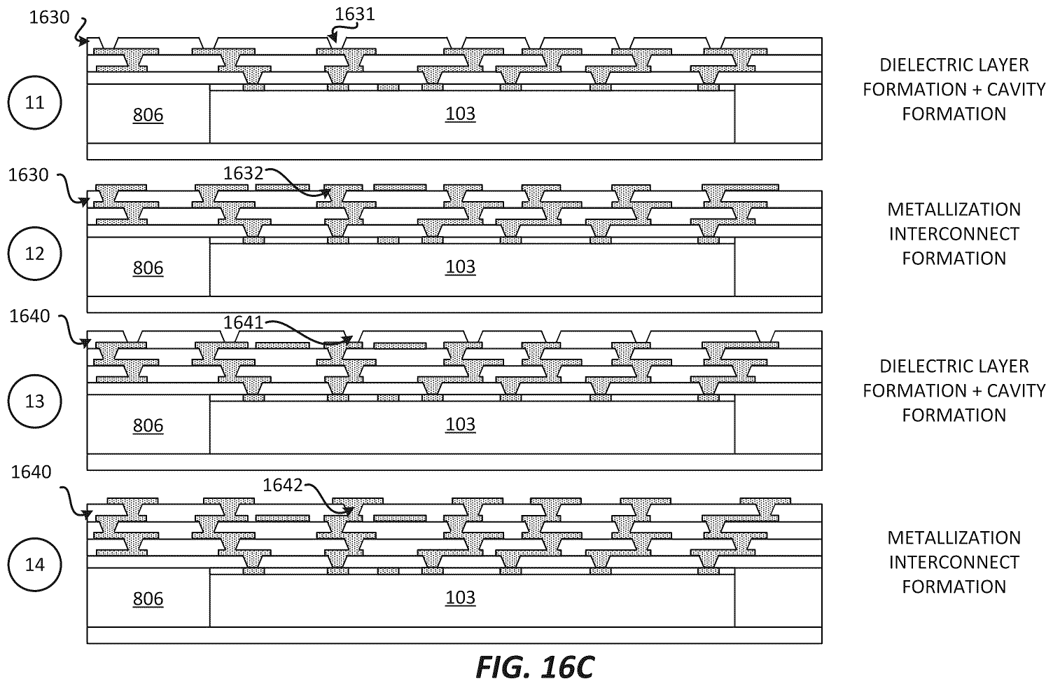

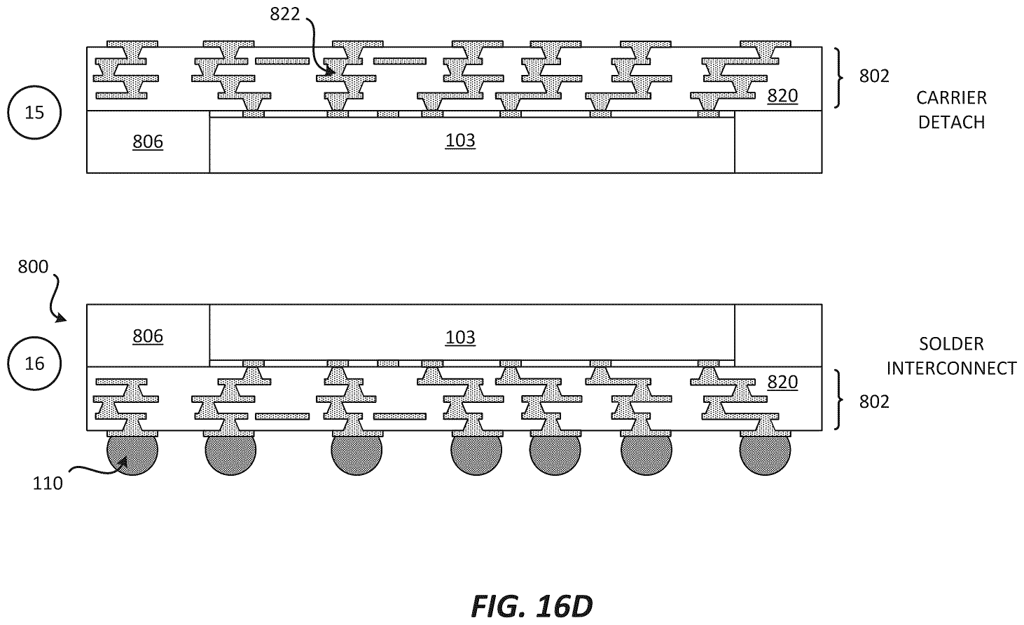

FIGS. 16A-16D illustrate an exemplary sequence for providing or fabricating a package that includes an integrated device and a metallization portion. In some implementations, the sequence of FIGS. 16A-16D may be used to provide or fabricate the package 800 of FIG. 8, or any of the packages described in the disclosure.

It should be noted that the sequence of FIGS. 16A-16D may combine one or more stages in order to simplify and/or clarify the sequence for providing or fabricating the package. In some implementations, the order of the processes may be changed or modified. In some implementations, one or more of processes may be replaced or substituted without departing from the scope of the disclosure. The sequence of FIGS. 16A-16D may be used to fabricate one package or several packages at a time (as part of a wafer).

Stage 1, as shown in FIG. 16A illustrates a state after a carrier 1600. An adhesive coat/layer may be provided over a surface of the carrier 1600.

Stage 2 illustrates a state after an integrated device 103 is placed on the carrier 1600. A pick and place process may be used to place the integrated device. The front side of the integrated device 103 may be placed on the carrier 1600. In some implementations, more than one integrated device may be placed on the carrier 1600. In some implementations, the integrated device 103 may include one or more shield structures as described in the disclosure. In some implementations, the integrated device 103 may include one or more inductors.

Stage 3 illustrates a state after an encapsulation layer 106 is formed over the carrier 1600 and the integrated device 103. The encapsulation layer 106 may encapsulate the integrated device 103. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

Stage 4 illustrates a state after portions of the encapsulation layer 106 may be removed. A grinding process may be used to remove a top portion of the encapsulation layer 106 and/or a back side of the integrated device 103.

Stage 5 illustrates a state after the carrier 1600 is decoupled from the integrated device 103 and the encapsulation layer 106. The carrier 1600 may be detached from the integrated device 103 and the encapsulation layer 106.

Stage 6 illustrates the integrated device 103 and the encapsulation layer 106 are placed on a carrier 1602. The back side of the integrated device 103 may be placed and coupled to the carrier 1602. There may be an adhesive coat on the carrier 1602. A pick and place process may be used to place the integrated device 103 and the encapsulation layer 106 on the carrier 1602.

Stage 7, as shown in FIG. 16B, illustrates a state after a dielectric layer 1610 is formed over the integrated device 103 and the encapsulation layer 106. A deposition and/or a lamination process may be used to form the dielectric layer 1610. The dielectric layer 1610 may be formed over a front side of the integrated device 103. Stage 7 also illustrates a state after a plurality of cavities 1611 are formed in the dielectric layer 1610. The plurality of cavities 1611 may be formed using an etching process (e.g., photo etching process). A masking process, an exposure process and/or a development process may be used to form the plurality of cavities 1611.

Stage 8 illustrates a state after metallization interconnects are formed in and over surfaces of the dielectric layer 1610 and in the plurality of cavities 1611. A plurality of metallization interconnects 1612 may be formed over (e.g., above) a first surface of the dielectric layer 1610 and the plurality of cavities 1611. A masking process, a plating process, an exposure process, a development process and/or an etching process may be used to form the plurality of metallization interconnects 1612.

Stage 9 illustrates a state after a dielectric layer 1620 is formed over the dielectric layer 1610 and the plurality of metallization interconnects 1612. A deposition and/or a lamination process may be used to form the dielectric layer 1620. Stage 9 also illustrates a state after a plurality of cavities 1621 are formed in the dielectric layer 1620. The plurality of cavities 1621 may be formed using an etching process (e.g., photo etching process). A masking process, an exposure process and/or a development process may be used to form the plurality of cavities 1621. The plurality of cavities 1621 may be formed over the plurality of metallization interconnects 1612, such that portions of the plurality of metallization interconnects 1612 are exposed.

Stage 10 illustrates a state after metallization interconnects are formed in and over surfaces of the dielectric layer 1620 and in the plurality of cavities 1621. A plurality of metallization interconnects 1622 may be formed over (e.g., above) a first surface of the dielectric layer 1620 and the plurality of cavities 1621. A masking process, a plating process, an exposure process, a development process and/or an etching process may be used to form the plurality of metallization interconnects 1622. The plurality of metallization interconnects 1622 may be coupled to the plurality of metallization interconnects 1612.

Stage 11, as shown in FIG. 16C, illustrates a state after a dielectric layer 1630 is formed over the dielectric layer 1630 and the plurality of metallization interconnects 1622. A deposition and/or a lamination process may be used to form the dielectric layer 1630. Stage 11 also illustrates a state after a plurality of cavities 1631 are formed in the dielectric layer 1630. The plurality of cavities 1631 may be formed using an etching process (e.g., photo etching process). A masking process, an exposure process and/or a development process may be used to form the plurality of cavities 1631. The plurality of cavities 1631 may be formed over the plurality of metallization interconnects 1622, such that portions of the plurality of metallization interconnects 1622 are exposed.

Stage 12 illustrates a state after metallization interconnects are formed in and over surfaces of the dielectric layer 1630 and in the plurality of cavities 1631. A plurality of metallization interconnects 1632 may be formed over (e.g., above) a first surface of the dielectric layer 1630 and the plurality of cavities 1631. A masking process, a plating process, an exposure process, a development process and/or an etching process may be used to form the plurality of metallization interconnects 1632. The plurality of metallization interconnects 1632 may be coupled to the plurality of metallization interconnects 1622.

Stage 13 illustrates a state after a dielectric layer 1640 is formed over the dielectric layer 1640 and the plurality of metallization interconnects 1632. A deposition and/or a lamination process may be used to form the dielectric layer 1640. Stage 13 also illustrates a state after a plurality of cavities 1641 are formed in the dielectric layer 1640. The plurality of cavities 1641 may be formed using an etching process (e.g., photo etching process). A masking process, an exposure process and/or a development process may be used to form the plurality of cavities 1641. The plurality of cavities 1641 may be formed over the plurality of metallization interconnects 1632, such that portions of the plurality of metallization interconnects 1632 are exposed.

Stage 14 illustrates a state after metallization interconnects are formed in and over surfaces of the dielectric layer 1640 and in the plurality of cavities 1641. A plurality of metallization interconnects 1642 may be formed over (e.g., above) a first surface of the dielectric layer 1640 and the plurality of cavities 1641. A masking process, a plating process, an exposure process, a development process and/or an etching process may be used to form the plurality of metallization interconnects 1642. The plurality of metallization interconnects 1642 may be coupled to the plurality of metallization interconnects 1632.

Stage 15, as shown in FIG. 16D, illustrates a state after the carrier 1602 is decoupled from the integrated device 103 and the encapsulation layer 106. The carrier 1602 may be detached from the integrated device 103 and the encapsulation layer 106. The dielectric layer 820 may represent the dielectric layer 1610, the dielectric layer 1620, the dielectric layer 1630 and/or the dielectric layer 1640. The plurality of metallization interconnects 822 may represent the plurality of metallization interconnects 1612, the plurality of metallization interconnects 1622, the plurality of metallization interconnects 1632 and/or the plurality of metallization interconnects 1642. In some implementations, the metallization portion 802 may include one or more shield structures as described in the disclosure. In some implementations, the metallization portion 802 may include one or more inductors.

Stage 16 illustrates a state after a plurality of solder interconnects 110 are coupled to the metallization portion 802. A solder reflow process may be used to couple the plurality of solder interconnects 110 to the plurality of metallization interconnects 822 of the metallization portion 802.

### Exemplary Flow Diagram of a Method for Fabricating a Package Comprising an Integrated Device and a Metallization Portion

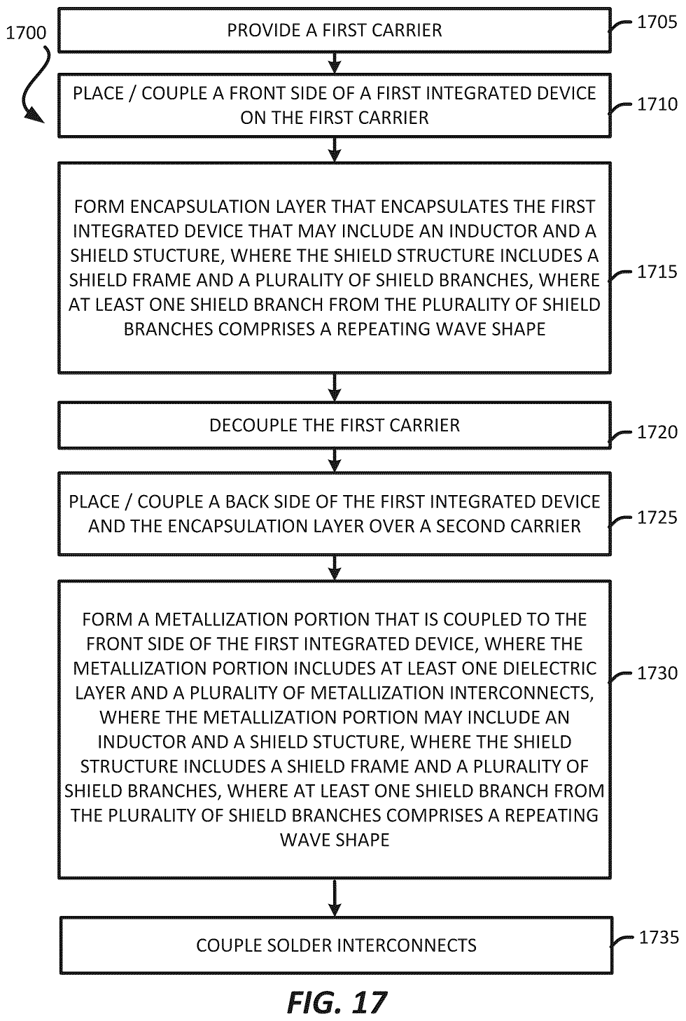

In some implementations, fabricating a package includes several processes. FIG. 17 illustrates an exemplary flow diagram of a method 1700 for providing or fabricating a package. In some implementations, the method 1700 of FIG. 17 may be used to provide or fabricate any of the packages of the disclosure. For example, the method 1700 of FIG. 17 may be used to fabricate the package 800.

It should be noted that the method 1700 of FIG. 17 may combine one or more processes in order to simplify and/or clarify the method for providing or fabricating a package. In some implementations, the order of the processes may be changed or modified. In some implementations, one or more of processes may be replaced or substituted without departing from the scope of the disclosure. The method 1700 of FIG. 17 may be used to fabricate one package or several packages at a time (as part of a wafer).

The method provides (at 1705) a carrier. In some implementations, the carrier may be provided with an adhesive. Stage 1 of FIG. 16A, illustrates and describes an example of providing a carrier 1600. An adhesive coat/layer may be located over a surface of the carrier 1600.

The method places (at 1710) a front side of an integrated device over the carrier. In some implementations, the front side of the integrated device is placed over a carrier that includes and adhesive. In some implementations, more than one integrated device may be placed over the carrier. Stage 2 of FIG. 16A, illustrates and describes an example of an integrated device 103 that is placed on the carrier 1600. A pick and place process may be used to place the integrated device. The front side of the integrated device 103 may be placed on the carrier 1600. In some implementations, more than one integrated device may be placed on the carrier 1600. In some implementations, the integrated device 103 may include one or more inductors. In some implementations, the integrated device 103 may include one or more shield structures as described in the disclosure.

The method forms (at 1715) an encapsulation layer that encapsulates the integrated device. The encapsulation layer may be coupled to the integrated device and the carrier. Stage 3 of FIG. 16A, illustrates and describes an example of an encapsulation layer 106 that is formed over the carrier 1600 and the integrated device 103. The encapsulation layer 106 may encapsulate the integrated device 103. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process. In some implementations, once the encapsulation layer 106 is provided, portions of the encapsulation layer 106 may be removed. For example, a grinding process may be used to remove a top portion of the encapsulation layer 106 and/or a back side of the integrated device 103. Stage 4 of FIG. 16A, illustrates and describes an example of removing a portion of the encapsulation layer 106.

The method decouples (at 1720) the carrier from the encapsulation layer and the integrated device. Stage 5 of FIG. 16A, illustrates and describes an example of the carrier 1600 that is decoupled from the integrated device 103 and the encapsulation layer 106. The carrier 1600 may be detached from the integrated device 103 and the encapsulation layer 106.

The method places (at 1725) a back side of the integrated device and the encapsulation layer over another carrier (e.g., second carrier). The carrier may include an adhesive. Stage 6 of FIG. 16B, illustrates and describes an example of the integrated device 103 and the encapsulation layer 106 that are placed on a carrier 1602. The back side of the integrated device 103 may be placed and coupled to the carrier 1602. There may be an adhesive coat on the carrier 1602. A pick and place process may be used to place the integrated device 103 and the encapsulation layer 106 on the carrier 1602.

The method forms (at 1730) a metallization portion that is coupled to the front side of the integrated device and the encapsulation layer. The metallization portion may include at least one dielectric layer and a plurality of metallization interconnects. The plurality of metallization interconnects may include a first metallization interconnect on a first metal layer and a second metallization interconnect on a first metal layer, where the second interconnect has a second thickness that is different from a first thickness of the first metallization interconnect. Forming the metallization portion may include forming at least one dielectric layer and forming include a first metallization interconnect on a first metal layer and a second metallization interconnect on a first metal layer. The second interconnect may have a second thickness that is different from a first thickness of the first metallization interconnect. Stage 7 of FIG. 16B through Stage 15 of FIG. 16D, illustrate examples of forming a metallization portion that is coupled to at least one integrated device. Different implementations may have different numbers of metal layers. Once the metallization portion is formed (at 1730), the method may decouple the second carrier from the integrated device and the encapsulation layer. In some implementations, the metallization portion 802 may include one or more inductors. In some implementations, the metallization portion 802 may include one or more shield structures as described in the disclosure.

The method couples (at 1735) a plurality of solder interconnects to the metallization interconnects of the metallization portion. Stage 16 of FIG. 16D, illustrates and describes an example of a plurality of solder interconnects 110 that are coupled to the metallization portion 802. A solder reflow process may be used to couple the plurality of solder interconnects 110 to the plurality of metallization interconnects 822 of the metallization portion 802.

### Exemplary Electronic Devices

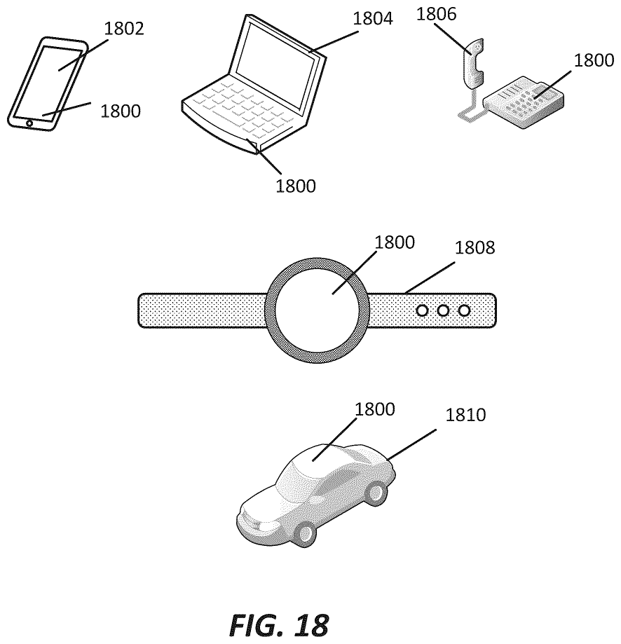

FIG. 18 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1802, a laptop computer device 1804, a fixed location terminal device 1806, a wearable device 1808, or automotive vehicle 1810 may include a device 1800 as described herein. The device 1800 may be, for example, any of the devices and/or integrated circuit (IC) packages described herein. The devices 1802, 1804, 1806 and 1808 and the vehicle 1810 illustrated in FIG. 18 are merely exemplary. Other electronic devices may also feature the device 1800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-13, 14A-14C, 15, 16A-16D and 17-18 may be rearranged and/or combined into a single component, process, feature or function or embodied in several components, processes, or functions. Additional elements, components, processes, and/or functions may also be added without departing from the disclosure. It should also be noted FIGS. 1-13, 14A-14C, 15, 16A-16D and 17-18 and its corresponding description in the present disclosure is not limited to dies and/or ICs. In some implementations, FIGS. 1-13, 14A-14C, 15, 16A-16D and 17-18 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following. further examples are described to facilitate the understanding of the disclosure.

Aspect 1: A device comprising an integrated device comprising a die substrate; and a die interconnection portion coupled to the die substrate; an inductor; and a shield structure. The shield structure comprises a shield frame; and a plurality of shield branches coupled to the shield frame, wherein at least one shield branch from the plurality of shield branches comprises a repeating wave shape.

Aspect 2: The device of aspect 1, wherein the at least one shield branch from the plurality of shield branches comprising a repeating wave shape comprises a repeating step wave shape.

Aspect 3: The device of aspects 1 through 2, wherein another shield branch from the plurality of shield branches comprises a repeating step wave shape.

Aspect 4: The device of aspects 1 through 3, wherein at least a portion of the shield frame defines an outer perimeter of the shield structure, and wherein the plurality of shield branches are a plurality of inner shield branches.

Aspect 5: The device of aspect 4, wherein the plurality of shield branches comprises a first plurality of shield branches coupled to a first portion of the shield frame, wherein the first plurality of shield branches extend away from the first portion of the shield frame in a first direction; a second plurality of shield branches coupled to a second portion of the shield frame, wherein the second plurality of shield branches extend away from the second portion of the shield frame in a second direction that is opposite to the first direction; a third plurality of shield branches coupled to a third portion of the shield frame, wherein the third plurality of shield branches extend away from the third portion of the shield frame in a third direction that is orthogonal to the first direction; and a fourth plurality of shield branches coupled to a fourth portion of the shield frame, wherein the fourth plurality of shield branches extend away from the fourth portion of the shield frame in a fourth direction that is opposite to the third direction.

Aspect 6: The device of aspect 5, wherein the first plurality of shield branches comprise a first shield branch that has a first length; and a second shield branch that has a second length.

Aspect 7: The device of aspects 5 through 6, wherein the first plurality of shield branches comprise a plurality of interleaved shield branches.

Aspect 8: The device of aspects 4 through 7, wherein the plurality of shield branches are laterally surrounded by at least a portion of the shield frame.

Aspect 9: The device of aspects 4 through 8, wherein the shield frame comprises a portion with a double E shape.

Aspect 10: The device of aspects 4 through 8, wherein the shield frame comprises a portion with a double E shape and an H shape.

Aspect 11: The device of aspects 1 through 10, wherein a shield branch from the plurality of shield branches comprises interconnects that change directions back and forth by 90 degrees.

Aspect 12: The device of aspects 1 through 11, wherein the inductor and the shield structure are implemented in the integrated device.

Aspect 13: The device of aspects 1 through 12, wherein the inductor and the shield structure are implemented in the die interconnection portion of the integrated device.

Aspect 14: The device of aspects 1 through 11, further comprising a package substrate coupled to the integrated device, wherein the shield structure is implemented in the package substrate.

Aspect 15: The device of aspects 1 through 11, further comprising a package substrate coupled to the integrated device, wherein the inductor and the shield structure are implemented in the package substrate.

Aspect 16: The device of aspects 1 through 11, further comprising a metallization portion coupled to the integrated device, wherein the shield structure is implemented in the metallization portion.

Aspect 17: The device of aspects 1 through 11, further comprising a metallization portion coupled to the integrated device, wherein the inductor and the shield structure are implemented in the metallization portion.

Aspect 18: The device of aspects 1 through 17, wherein the shield structure is symmetrical along the X-axis and/or the Y-axis.

Aspect 19: The device of aspects 1 through 17, wherein the shield structure is asymmetrical along the X-axis and/or the Y-axis.

Aspect 20: The device of aspects 1 through 19, wherein the shield structure is configured to be coupled to ground.

Aspect 21: The device of aspects 1 through 20, wherein the device is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 22: An integrated device comprising a die substrate, a die interconnection portion coupled to the die substrate, an inductor and a shield structure. The shield structure comprises a shield frame and a plurality of shield branches coupled to the shield frame, wherein at least one shield branch from the plurality of shield branches comprises a repeating wave shape.

Aspect 23: The integrated device of aspect 22, wherein another shield branch from the plurality of shield branches comprises a repeating step wave shape.

Aspect 24: The integrated device of aspects 22 through 23, wherein the plurality of shield branches comprises a first plurality of shield branches coupled to a first portion of the shield frame, wherein the first plurality of shield branches extend away from the first portion of the shield frame in a first direction; a second plurality of shield branches coupled to a second portion of the shield frame, wherein the second plurality of shield branches extend away from the second portion of the shield frame in a second direction that is opposite to the first direction; a third plurality of shield branches coupled to a third portion of the shield frame, wherein the third plurality of shield branches extend away from the third portion of the shield frame in a third direction that is orthogonal to the first direction; and a fourth plurality of shield branches coupled to a fourth portion of the shield frame, wherein the fourth plurality of shield branches extend away from the fourth portion of the shield frame in a fourth direction that is opposite to the third direction.

Aspect 25: A method for fabricating an integrated device. The method provides a die substrate. The method forms a die interconnection portion coupled to the die substrate, where forming the die interconnection portion includes forming a plurality of die interconnects. The plurality of die interconnects comprises an inductor and a shield structure. The shield structure includes a shield frame and a plurality of shield branches coupled to the shield frame, wherein at least one shield branch from the plurality of shield branches comprises a repeating wave shape.

Aspect 26: The method of aspect 25, wherein the at least one shield branch from the plurality of shield branches comprising a repeating wave shape comprises a repeating step wave shape.

Aspect 27: The method of aspect 25, wherein another shield branch from the plurality of shield branches comprises a repeating step wave shape.

Aspect 28: The method of aspects 25 through 27, wherein at least a portion of the shield frame defines an outer perimeter of the shield structure, and wherein the plurality of shield branches are a plurality of inner shield branches.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
an integrated device comprising:
a die substrate; and
a die interconnection portion coupled to the die substrate;
an inductor; and
a shield structure comprising:
a shield frame; and
a plurality of shield branches coupled to the shield frame, wherein at least one shield branch from the plurality of shield branches comprises a repeating wave shape.

2. The device of claim 1, wherein the at least one shield branch from the plurality of shield branches comprising a repeating wave shape comprises a repeating step wave shape.

3. The device of claim 1, wherein another shield branch from the plurality of shield branches comprises a repeating step wave shape.

4. The device of claim 1,
wherein at least a portion of the shield frame defines an outer perimeter of the shield structure, and
wherein the plurality of shield branches are a plurality of inner shield branches.

5. The device of claim 1, wherein the plurality of shield branches comprises:
a first plurality of shield branches coupled to a first portion of the shield frame, wherein the first plurality of shield branches extend away from the first portion of the shield frame in a first direction;
a second plurality of shield branches coupled to a second portion of the shield frame, wherein the second plurality of shield branches extend away from the second portion of the shield frame in a second direction that is opposite to the first direction;
a third plurality of shield branches coupled to a third portion of the shield frame, wherein the third plurality of shield branches extend away from the third portion of the shield frame in a third direction that is orthogonal to the first direction; and
a fourth plurality of shield branches coupled to a fourth portion of the shield frame, wherein the fourth plurality of shield branches extend away from the fourth portion of the shield frame in a fourth direction that is opposite to the third direction.

6. The device of claim 5, wherein the first plurality of shield branches comprise:
a first shield branch that has a first length; and
a second shield branch that has a second length.

7. The device of claim 5, wherein the first plurality of shield branches comprise a plurality of interleaved shield branches.

8. The device of claim 4, wherein the plurality of shield branches are laterally surrounded by at least a portion of the shield frame.

9. The device of claim 4, wherein the shield frame comprises a portion with a double E shape.

10. The device of claim 4, wherein the shield frame comprises a portion with a double E shape and an H shape.

11. The device of claim 1, wherein a shield branch from the plurality of shield branches comprises interconnects that change directions back and forth by 90 degrees.

12. The device of claim 1, wherein the inductor and the shield structure are implemented in the integrated device.

13. The device of claim 1, wherein the inductor and the shield structure are implemented in the die interconnection portion of the integrated device.

14. The device of claim 1, further comprising a package substrate coupled to the integrated device, wherein the shield structure is implemented in the package substrate.

15. The device of claim 1, further comprising a package substrate coupled to the integrated device, wherein the inductor and the shield structure are implemented in the package substrate.

16. The device of claim 1, further comprising a metallization portion coupled to the integrated device, wherein the shield structure is implemented in the metallization portion.

17. The device of claim 1, further comprising a metallization portion coupled to the integrated device, wherein the inductor and the shield structure are implemented in the metallization portion.

18. The device of claim 1, wherein the shield structure is symmetrical along the X-axis and/or the Y-axis.

19. The device of claim 1, wherein the shield structure is asymmetrical along the X-axis and/or the Y-axis.

20. The device of claim 1, wherein the shield structure is configured to be coupled to ground.

21. The device of claim 1, wherein the device is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

22. An integrated device comprising:
a die substrate; and
a die interconnection portion coupled to the die substrate;
an inductor; and
a shield structure comprising:
a shield frame; and
a plurality of shield branches coupled to the shield frame, wherein at least one shield branch from the plurality of shield branches comprises a repeating wave shape.

23. The integrated device of claim 22, wherein another shield branch from the plurality of shield branches comprises a repeating step wave shape.

24. The integrated device of claim 22, wherein the plurality of shield branches comprises:
a first plurality of shield branches coupled to a first portion of the shield frame, wherein the first plurality of shield branches extend away from the first portion of the shield frame in a first direction;
a second plurality of shield branches coupled to a second portion of the shield frame, wherein the second plurality of shield branches extend away from the second portion of the shield frame in a second direction that is opposite to the first direction;
a third plurality of shield branches coupled to a third portion of the shield frame, wherein the third plurality of shield branches extend away from the third portion of the shield frame in a third direction that is orthogonal to the first direction; and
a fourth plurality of shield branches coupled to a fourth portion of the shield frame, wherein the fourth plurality of shield branches extend away from the fourth portion of the shield frame in a fourth direction that is opposite to the third direction.

25. A method for fabricating an integrated device, comprising:
providing a die substrate;
forming a die interconnection portion coupled to the die substrate, wherein forming the die interconnection portion includes forming a plurality of die interconnects, wherein the plurality of die interconnects comprises:
an inductor;
a shield structure comprising:
a shield frame; and
a plurality of shield branches coupled to the shield frame, wherein at least one shield branch from the plurality of shield branches comprises a repeating wave shape.

26. The method of claim 25, wherein the at least one shield branch from the plurality of shield branches comprising a repeating wave shape comprises a repeating step wave shape.

27. The method of claim 25, wherein another shield branch from the plurality of shield branches comprises a repeating step wave shape.

28. The method of claim 25,
wherein at least a portion of the shield frame defines an outer perimeter of the shield structure, and
wherein the plurality of shield branches are a plurality of inner shield branches.
